(19) United States
(12) Patent Application Publication
(10) Pub. No.: US 2026/0282717 A1
(43) Pub. Date: Sep. 17, 2026

(54) DISPLAY DEVICE WITH WAVELENGTH-SPECIFIC TRANSMITTANCE OR REFLECTIVITY AND ELECTRONIC DEVICE INCLUDING THE SAME

(71) Applicant: SAMSUNG DISPLAY CO., LTD., YONGIN-SI (KR)

(72) Inventors: Hyo Joon KIM, YONGIN-SI (KR); Ju Youn SON, YONGIN-SI (KR); Soon Gi PARK, YONGIN-SI (KR); Ju Hwa HA, YONGIN-SI (KR)

(21) Appl. No.: 19/335,468

(22) Filed: Sep. 22, 2025

(30) Foreign Application Priority Data
Mar. 12, 2025 (KR) 10-2025-0031941

(51) Int. Cl. H10K 59/80

(52) U.S. Cl. CPC H10K 59/878; H10K 59/879

(57) ABSTRACT

An electronic device includes a display device that has a display panel, a first polarizing film located on the display panel, a first phase retardation film located on the first polarizing film, a reflection control film located on the first phase retardation film, a first lens located on the reflection control film, a second lens located on the first lens, a second phase retardation film located on the second lens, a second polarizing film located on the second phase retardation film, and a third lens located on the second polarizing film, wherein a function of a transmittance and a reflectivity of the reflection control film in respect to light of a first wavelength range is different from the function of a transmittance and a reflectivity of the reflection control film in respect to light of a second wavelength range.

### CROSS-REFERENCE

This application claims priority under 35 U.S.C. § 119 to Korean Patent Application No. 10-2025-0031941, filed on Mar. 12, 2025 in the Korean Intellectual Property Office, the entire disclosure of which is herein incorporated by reference.

### FIELD

The present disclosure generally relates to display technology, and more particularly relates to a display device and an electronic device including the same with different internal transmittance or reflectivity for different wavelengths of light.

### INTRODUCTION

A head-mounted display (HMD) is an image display device that is worn on a user's head in the form of glasses or helmet to form a focus point at a relatively close distance in front of the user's eyes. For example, the head-mounted display may implement virtual reality (VR), augmented reality (AR), intelligent sensory augmentation, or the like.

The head-mounted display may magnify an image displayed on a relatively small display device by using a plurality of lenses, and may display the magnified image to the user. Therefore, the display device applied to the head-mounted display may provide relatively high-resolution images, such as images with a resolution of 3000 Pixels Per Inch (PPI) or higher. For example, an organic light-emitting diode on silicon (OLEDoS) display device, which is a small organic light-emitting type of display device that supports high-resolution, may be used as the display device applied to the head-mounted display. The OLEDoS is an image display device in which an organic light-emitting diode (OLED) is located on a semiconductor wafer substrate, such as one including complementary metal oxide semiconductor (CMOS) technology.

### SUMMARY

Embodiments of the present disclosure may provide a display device in which color temperature characteristics may be optimized, and an electronic device including the same.

Embodiments of the present disclosure may provide a display device with a minimized ghosting phenomenon, and an electronic device including the same.

However, embodiments of the present disclosure are not necessarily restricted to those set forth herein. The above and other embodiments of the present disclosure will become more apparent to those of ordinary skill in the art to which the present disclosure pertains by referencing the detailed description of the present disclosure that is provided below.

According to an embodiment of the present disclosure, there is provided a display device including: a display panel; a first polarizing film located on the display panel; a first phase retardation film located on the first polarizing film; a reflection control film located on the first phase retardation film; a first lens located on the reflection control film; a second lens located on the first lens; a second phase retardation film located on the second lens; a second polarizing film located on the second phase retardation film; and a third lens located on the second polarizing film, and a first function of a transmittance and a reflectivity of the reflection control film in respect to light of a first wavelength range is different from the first function of a transmittance and a reflectivity of the reflection control film in respect to light of a second wavelength range.

In an embodiment of the display device, the first function is a product of transmittance and reflectivity in respect to light of a same wavelength.

In an embodiment of the display device, the display panel emits light of the first wavelength range, the second wavelength range, and a third wavelength range, and the first function of the transmittance and the reflectivity of the reflection control film in respect to the light of the first wavelength range is smaller than the first function of the transmittance and the reflectivity of the reflection control film in respect to the light of the second wavelength range and the third wavelength range.

In an embodiment of the display device, the first wavelength range is a red wavelength band from about 620 nm to about 640 nm, the second wavelength range is a green wavelength band about 515 nm to about 535 nm, and the third wavelength range is a blue wavelength band from about 450 nm to about 470 nm, and a full width at half maximum of main peak wavelengths included in the first wavelength range and the second wavelength range is about 30 nm to about 40 nm, and a full width at half maximum of main peak wavelength included in the third wavelength range is about 20 nm to about 30 nm.

In an embodiment of the display device, the first function of the transmittance and the reflectivity of the reflection control film in respect to light of the first to third wavelength ranges is greater than the first function of the transmittance and the reflectivity of the reflection control film in respect to the light of a range other than the first to third wavelength ranges.

In an embodiment of the display device, a second function of the transmittance and the reflectivity of the reflection control film in respect to light of the first wavelength range is substantially the same as the second function of the transmittance and the reflectivity of the reflection control film in respect to light of the second wavelength range.

In an embodiment of the display device, the second function is a sum of transmittance and reflectivity in respect to light of a same wavelength,
and the sum of the transmittance and the reflectivity of the reflection control film in respect to the same wavelength within the second wavelength range is substantially 100%.

In an embodiment of the display device, the reflection control film includes multiple films in which low-refractive-index films and high-refractive-index films are alternatively stacked, and the low-refractive-index film contains at least one among silicon oxide and silicon oxynitride, and the high-refractive-index film contains at least one among silicon nitride and titanium oxide.

In an embodiment of the display device, the first lens, the second lens, and the third lens are spaced apart from each other, the display device further including at least one reflective coating film located between the first lens and the second lens and between the second lens and the third lens, respectively.

In an embodiment of the display device, the first lens, the second lens, and the third lens are combined to form a triplet lens, the display device further including: a first adhesive layer located between the first lens and the second lens; and a second adhesive layer located between the second lens and the third lens.

In an embodiment of the display device, the first lens and the second lens are combined to form a doublet lens, and the doublet lens and the third lens are spaced apart from each other, the display device further including: an adhesive layer located between the first lens and the second lens; and at least one reflective coating film located between the doublet lens and the third lens.

In an embodiment of the display device, the second lens and the third lens are combined to form a doublet lens, and the doublet lens and the first lens are spaced apart from each other, the display device further including: an adhesive layer located between the second lens and the third lens; and at least one reflective coating film located between the doublet lens and the first lens.

In an embodiment of the display device, the transmittance of the reflection control film in respect to light of the first wavelength range is different from the transmittance of the reflection control film in respect to light of the second wavelength range.

In an embodiment of the display device, the sum of the transmittance and a reflectivity of the reflection control film in respect to the same wavelength range is substantially 100%.

According to an embodiment of the present disclosure, there is provided a display device including: a display panel; and a reflection control film located on the display panel, and a first function of a transmittance and a reflectivity of the reflection control film in respect to light of a first wavelength range is different from the first function of a transmittance and a reflectivity of the reflection control film in respect to light of a second wavelength range, and a second function of the transmittance and the reflectivity of the reflection control film in respect to light of the first wavelength range is substantially the same as the second function of the transmittance and the reflectivity of the reflection control film in respect to light of the second wavelength range.

In an embodiment of the display device, the first function is a product of transmittance and reflectivity in respect to light of a same wavelength, and the second function is a sum of transmittance and reflectivity in respect to light of the same wavelength.

In an embodiment of the display device, further included are a first polarizing film disposed on the display panel; and a first phase retardation film disposed on the first polarizing film, and the reflection control film is disposed on the first phase retardation film.

In an embodiment of the display device, further included are a first lens disposed on the reflection control film; a second lens disposed on the first lens; a second phase retardation film disposed on the second lens; a second polarizing film disposed on the second phase retardation film; and a third lens disposed on the second polarizing film.

According to an embodiment of the present disclosure, there is provided an electronic device including a display device displaying an image, a processor providing an image driving signal to the display device, and a power module supplying power to the display device and the processor, wherein the display device includes, a display panel, a first polarizing film located on the display panel, a first phase retardation film located on the first polarizing film, a reflection control film located on the first phase retardation film, a first lens located on the reflection control film, a second lens located on the first lens, a second phase retardation film located on the second lens, a second polarizing film located on the second phase retardation film, and a third lens located on the second polarizing film, wherein the product of a transmittance and a reflectivity of the reflection control film in respect to light of a first wavelength range is different from the product of the transmittance and the reflectivity of the reflection control film in respect to light of a second wavelength range.

In an embodiment of the electronic device, the sum of the transmittance and the reflectivity of the reflection control film in respect to light of the first wavelength range is substantially the same as the sum of the transmittance and the reflectivity of the reflection control film in respect to light of the second wavelength range.

In accordance with the display device and the electronic device including the same according to an embodiment of the present disclosure, the color temperature characteristics may be optimized.

In accordance with the display device and the electronic device including the same according to an embodiment of the present disclosure, a ghosting phenomenon may be minimized.

It should be noted that embodiments of the present disclosure are not necessarily limited to those described above and other embodiments of the present disclosure may become apparent to those skilled in the art based on the following descriptions.

### BRIEF DESCRIPTION OF THE DRAWINGS

The aforementioned and other embodiments of the present disclosure will become more apparent by describing in detail by way of example illustrative embodiments thereof with reference to the attached drawings, in which

FIG. 1 is an exploded perspective view diagram showing a display device according to an embodiment;

FIG. 2 is a block diagram illustrating an example of the display panel shown in FIG. 1;

FIG. 3 is an equivalent circuit diagram of a first sub-pixel according to an embodiment;

FIG. 4 is a layout diagram illustrating an example of a display panel according to an embodiment;

FIG. 5 is a layout diagram showing an example of the display area of FIG. 4;

FIG. 6 is a layout diagram showing another example of the display area of FIG. 4;

FIG. 7 is a cross-sectional view diagram illustrating an example of a display panel taken along the line I1-I1′ of FIG. 5;

FIG. 8 is a cross-sectional view diagram illustrating another example of a display panel taken along the line I1-I1′ of FIG. 5;

FIG. 9 is a schematic cross-sectional view diagram illustrating a display element layer, lenses, and an optical module of a display device according to an embodiment;

FIG. 10 is a cross-sectional view diagram showing a display device according to an embodiment;

FIG. 11 is a schematic diagram showing a display device according to an embodiment;

FIG. 12 is a schematic diagram illustrating the path and polarization state of light emitted from a display device according to an embodiment;

FIG. 13 is a graphical diagram illustrating graphs showing wavelength-specific transmittance of a reflection control film and a graph showing an emission spectrum of a display panel according to an embodiment versus a comparative example;

FIG. 14 is a graphical diagram illustrating a graph showing wavelength-specific transmittance of a display device according to an embodiment versus a comparative example;

FIG. 15 is a pictorial diagram for explaining a ghosting phenomenon of a display device according to a comparative example;

FIG. 16 is a pictorial diagram for explaining a ghosting phenomenon of a display device according to an embodiment;

FIG. 17 is a graphical diagram illustrating wavelength-specific transmittance of a reflection control film and an emission spectrum of a display panel according to an embodiment versus a comparative example;

FIG. 18 is a cross-sectional view diagram showing a display device according to an embodiment;

FIG. 19 is a schematic diagram showing a display device according to an example of the embodiment of FIG. 18;

FIG. 20 is a cross-sectional view diagram showing a display device according to an embodiment;

FIG. 21 is a schematic diagram showing a display device according to an example of the embodiment of FIG. 20;

FIG. 22 is a cross-sectional view diagram showing a display device according to an embodiment;

FIG. 23 is a schematic diagram showing a display device according to an example of the embodiment of FIG. 22;

FIG. 24 is an exploded perspective view diagram illustrating a head-mounted display according to an embodiment;

FIG. 25 is a perspective view diagram showing an augmented reality content-providing device according to an embodiment;

FIG. 26 is a rear exploded perspective view diagram of the augmented reality content-providing device of FIG. 25;

FIG. 27 is a front exploded perspective view diagram of the augmented reality content-providing device of FIG. 25;

FIG. 28 is a block diagram of an electronic device according to an embodiment; and

FIG. 29 is a schematic view diagram of electronic devices according to various configurations of an embodiment.

### DETAILED DESCRIPTION

The inventive concept of the present disclosure will hereinafter be described in greater detail by way of example with reference to the accompanying drawings, in which illustrative embodiments are shown. This inventive concept may, however, be embodied in different forms and should not be construed as necessarily limited to the embodiments set forth herein. Rather, these embodiments are provided so that this disclosure may be thorough and complete, and fully convey the scope of the inventive concept to those skilled in the art.

In the description that follows, when a layer is referred to as being “on” another layer or substrate, it can be directly on the other layer or substrate, or intervening layers may also be present unless stated to the contrary. Moreover, the same or like reference numerals or indicia may be used to indicate the same or like components throughout the specification.

In an embodiment, a display device includes a display panel and a reflection control film located on the display panel, and a first function of a transmittance and a reflectivity of the reflection control film in respect to light of a first wavelength range is different from the first function of a transmittance and a reflectivity of the reflection control film in respect to light of a second wavelength range. Moreover, a second function of the transmittance and the reflectivity of the reflection control film in respect to light of the first wavelength range is substantially the same as the second function of the transmittance and the reflectivity of the reflection control film in respect to light of the second wavelength range. For example, the first function may be a product and the second function may be a sum. Accordingly, color temperature characteristics may be optimized and/or a ghosting phenomena may be minimized.

In an embodiment, a display device includes a display panel, a first polarizing film located on the display panel, a first phase retardation film located on the first polarizing film, and a reflection control film located on the first phase retardation film, and a transmittance of the reflection control film in respect to light of a first wavelength range is different from a transmittance of the reflection control film in respect to light of a second wavelength range.

In an embodiment, a display device includes a display panel, a reflection control film located on the display panel, a first lens located on the reflection control film, a second lens located on the first lens, a second phase retardation film located on the second lens, a second polarizing film located on the second phase retardation film, and a third lens located on the second polarizing film, and a reflectivity of the reflection control film in respect to light of a first wavelength range is different from a reflectivity of the reflection control film in respect to light of a second wavelength range.

In an embodiment, a display device includes a display panel, a first polarizing film located on the display panel, a first phase retardation film located on the first polarizing film, a reflection control film located on the first phase retardation film, a first lens located on the reflection control film, a second lens located on the first lens, a second phase retardation film located on the second lens, a second polarizing film located on the second phase retardation film, and a third lens located on the second polarizing film, and a function of a transmittance and a reflectivity of the reflection control film in respect to light of a first wavelength range is different from a function of a transmittance and a reflectivity of the reflection control film in respect to light of a second wavelength range.

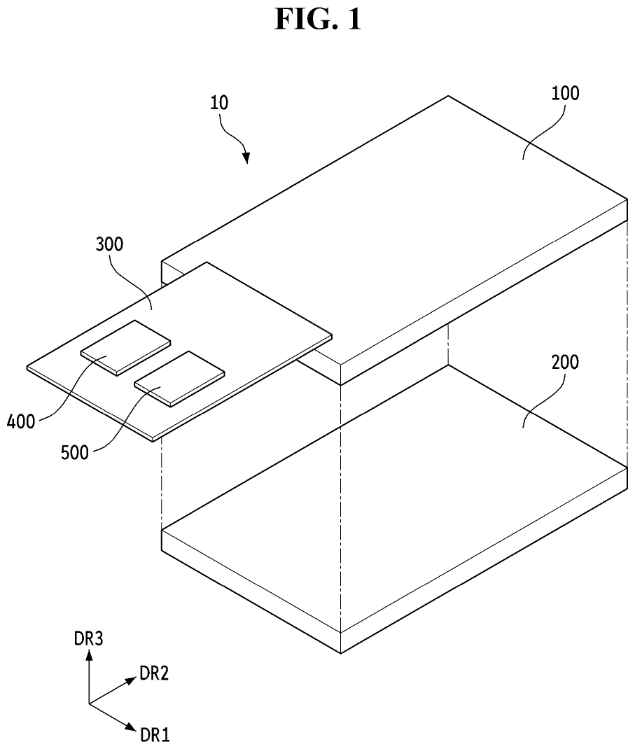

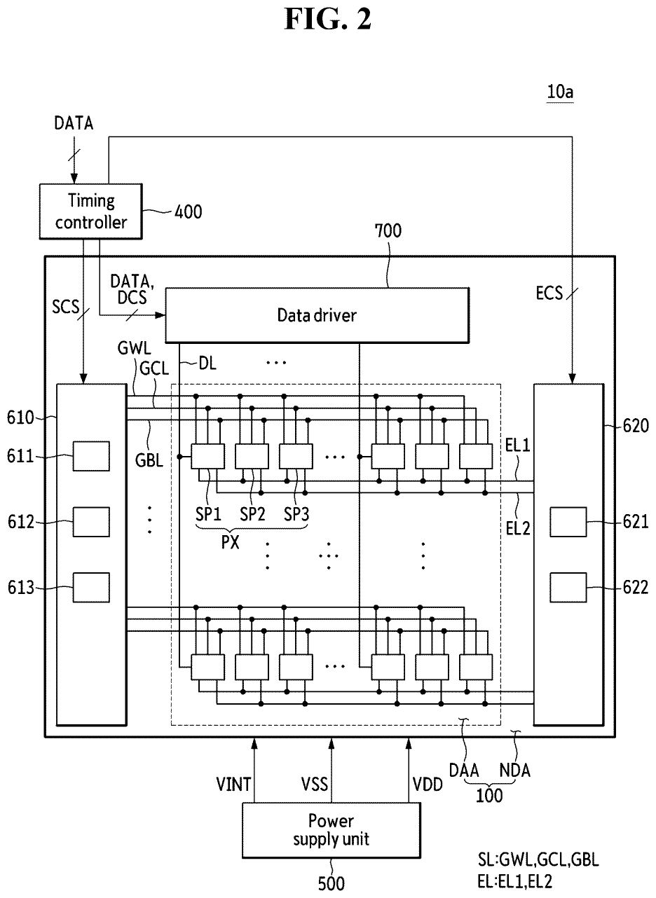

FIG. 1 shows a display device according to an embodiment, indicated generally by the reference indicator 10. FIG. 2 shows an example of the display device 10 of FIG. 1, indicated generally by the reference indicator 10a.

Referring to FIGS. 1 and 2, a display device 10 according to an embodiment, such as the display device 10a, may display a moving image or a still image. The display device 10a according to an embodiment may be applied to portable electronic devices such as a mobile phone, a smartphone, a tablet computer, a personal computer (PC), a mobile communications terminal, an electronic organizer, an electronic book, a portable multimedia player (PMP), a navigation system, an ultra mobile PC (UMPC) or the like. For example, the display device 10a according to an embodiment may be applied as a display unit of a television, a laptop computer, a computer monitor, an electronic billboard, an Internet-of-Things (IoT) terminal, or the like. Alternatively, the display device 10a according to an embodiment may be applied to a smart watch, a watch phone, a head-mounted display (HMD) for implementing virtual reality and augmented reality, or the like.

The display device 10a according to an embodiment includes a display panel 100, a heat dissipation layer 200, a circuit board 300, a timing control circuit 400, and a power supply circuit 500.

The display panel 100 may have a planar shape similar to a quadrilateral shape. For example, the display panel 100 may have a planar shape similar to a quadrilateral shape, having a short side of a first direction DR1 and a long side of a second direction DR2 intersecting the first direction DR1. In the display panel 100, a corner where a short side in the first direction DR1 and a long side in the second direction DR2 meet may be right-angled or rounded with a selected curvature. The planar shape of the display panel 100 is not necessarily limited to a quadrilateral shape, and may be a shape similar to another polygonal shape, a circular shape, or an elliptical shape. The planar shape of the display device 10a may conform to the planar shape of the display panel 100, but embodiments of the present disclosure is not necessarily limited thereto.

In the illustrated FIGURE, the first direction DR1 and the second direction DR2 cross each other as horizontal directions. For example, the first direction DR1 and the second direction DR2 may be perpendicular or orthogonal to each other. In addition, a third direction DR3 crosses the first direction DR1 and the second direction DR2, and may be, for example, perpendicular or orthogonal to each of the other two directions. Unless otherwise defined, in the present specification, directions indicated by arrows of the first to third directions DR1, DR2, and DR3 may be referred to as one side, and the opposite directions thereto may be referred to as the other side. Also, the terms “above,” “upper side,” “upper portion,” “top,” and “top surface,” as used herein, may refer to a direction indicated by an arrow in the drawing in the third direction DR3 based on the drawings, and the terms “below,” “lower side,” “lower portion,” “bottom,” and “bottom surface,” as used herein, may refer to a direction opposite to the direction indicated by the arrow in the third direction DR3 based on the drawings.

As shown in FIG. 2, the display panel 100 includes a plurality of pixels PX, a plurality of scan lines SL (see FIG. 2 legend), a plurality of emission control lines EL (see FIG. 2 legend), a plurality of data lines DL, a scan driver 610, an emission driver 620, and a data driver 700. The display panel 100 may be divided into a display area DAA displaying an image and a non-display area NDA not displaying an image.

The plurality of pixels PX may be arranged in the display area DAA. The plurality of pixels PX may be arranged in a two-dimensional matrix form along the first direction DR1 and the second direction DR2. The plurality of scan lines SL and the plurality of emission control lines EL may extend in the first direction DR1, while being arranged in the second direction DR2. The plurality of data lines DL may extend in the second direction DR2, while being arranged in the first direction DR1.

The plurality of scan lines SL may include a plurality of write scan lines GWL, a plurality of control scan lines GCL, and a plurality of bias scan lines GBL. The plurality of emission control lines EL include a plurality of first emission control lines ECL1 and a plurality of second emission control lines ECL2.

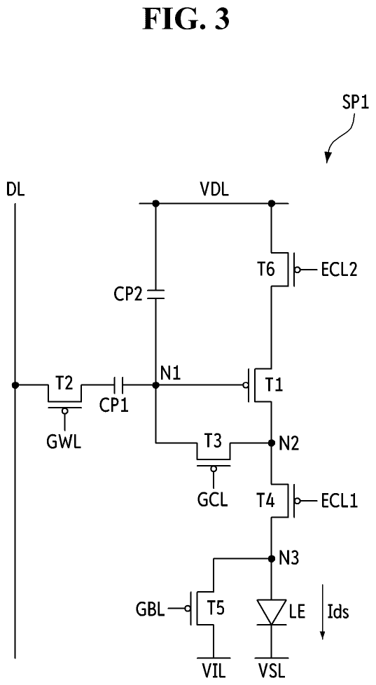

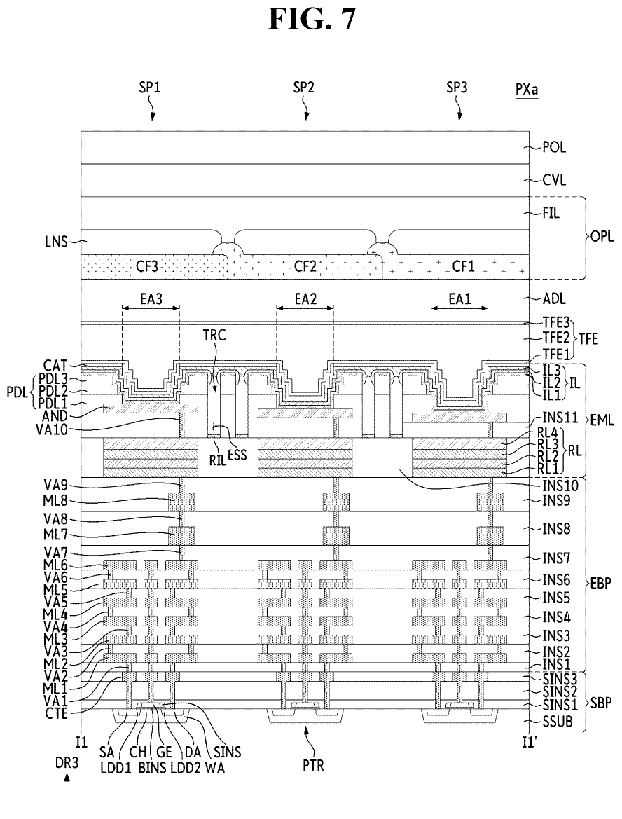

The plurality of pixels PX include a plurality of sub-pixels SP1, SP2, and SP3. The plurality of sub-pixels SP1, SP2, and SP3 may include a plurality of pixel transistors such as shown in FIG. 3, described infra, and the plurality of pixel transistors may be formed by a semiconductor process and located on a semiconductor substrate SSUB such as shown in FIG. 7, described infra. For example, the plurality of pixel transistors of the data driver 700 may be formed as complementary metal oxide semiconductor (CMOS) transistors, but embodiments of the present disclosure is not necessarily limited thereto.

Each of the plurality of sub-pixels SP1, SP2, and SP3 may be connected to one write scan line GWL, one control scan line GCL, one bias scan line GBL, one first emission control line ECL1, one second emission control line ECL2, and one data line DL. Each of the plurality of sub-pixels SP1, SP2, and SP3 may receive a data voltage of the data line DL in response to a write scan signal of the write scan line GWL, and emit light from the light-emitting element based on the data voltage.

The scan driver 610, the emission driver 620, and the data driver 700 may be located in the non-display area NDA.

The scan driver 610 includes a plurality of scan transistors, and the emission driver 620 includes a plurality of emission transistors. The plurality of scan transistors and the plurality of emission transistors may be formed on the semiconductor substrate SSUB, such as shown in FIG. 7, described infra, through a semiconductor process. For example, the plurality of scan transistors and the plurality of light-emitting transistors may be formed as CMOS transistors, but embodiments of the present disclosure is not necessarily limited thereto.

The scan driver 610 may include a write scan signal output unit 611, a control scan signal output unit 612, and a bias scan signal output unit 613. Each of the write scan signal output unit 611, the control scan signal output unit 612, and the bias scan signal output unit 613 may receive a scan timing control signal SCS from the timing control circuit 400. The write scan signal output unit 611 may generate write scan signals based on the scan timing control signal SCS of the timing control circuit 400 and output them sequentially to the write scan lines GWL. The control scan signal output unit 612 may generate control scan signals in response to the scan timing control signal SCS and sequentially output them to the control scan lines GCL. The bias scan signal output unit 613 may generate bias scan signals based on the scan timing control signal SCS and output them sequentially to the bias scan lines GBL.

The emission driver 620 includes a first emission control driver 621 and a second emission control driver 622. Each of the first emission control driver 621 and the second emission control driver 622 may receive an emission timing control signal ECS from the timing control circuit 400. The first emission control driver 621 may generate first emission control signals based on the emission timing control signal ECS and sequentially output them to the first emission control lines ECL1. The second emission control driver 622 may generate second emission control signals based on the emission timing control signal ECS and sequentially output them to the second emission control lines ECL2.

The data driver 700 may include a plurality of data transistors, and the plurality of data transistors may be formed on the semiconductor substrate SSUB, such as shown in FIG. 7, described infra, through a semiconductor process. For example, the plurality of data transistors may be formed as CMOS transistors, but embodiments of the present disclosure is not necessarily limited thereto.

The data driver 700 may receive digital video data signal DATA and a data timing control signal DCS from the timing control circuit 400. The data driver 700 converts the digital video data signal DATA into analog data voltages based on the data timing control signal DCS and outputs the analog data voltages to data lines DL. In this case, the sub-pixels SP1, SP2, and SP3 may be selected by the write scan signal of the scan driver 610, and data voltages may be supplied to the selected sub-pixels SP1, SP2, and SP3.

The heat dissipation layer 200 may overlap the display panel 100 in a third direction DR3, which is a thickness direction of the display panel 100. The heat dissipation layer 200 may be located on one surface, e.g., the rear surface, of the display panel 100. The heat dissipation layer 200 serves to dissipate heat generated from the display panel 100. The heat dissipation layer 200 may include a metal layer having high thermal conductivity, such as graphite, silver (Ag), copper (Cu), or aluminum (Al).

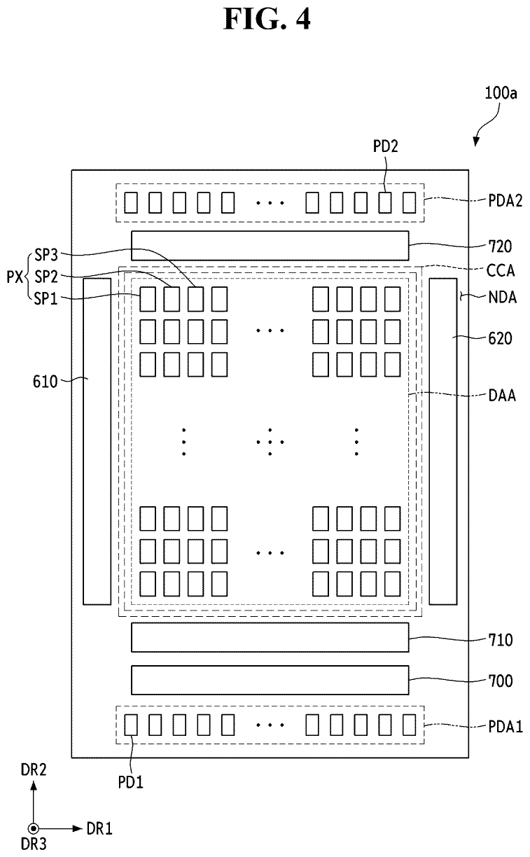

The circuit board 300 may be electrically connected to a plurality of first pads PD1, such as shown in FIG. 4, described infra, of a first pad portion PDA1, such as shown in FIG. 4, described infra, of the display panel 100 by using a conductive adhesive member such as an anisotropic conductive film. The circuit board 300 may be a flexible printed circuit board with a flexible material, or a flexible film.

Although the circuit board 300 is illustrated in FIG. 1 as being unfolded, the circuit board 300 may be bent, for example. In this case, one end of the circuit board 300 may be located on the rear surface of the display panel 100 and/or the rear surface of the heat dissipation layer 200. The other end of the circuit board 300 may be connected to the plurality of first pads PD1, such as shown in FIG. 4, described infra, of the first pad portion PDA1, such as shown in FIG. 4, described infra, of the display panel 100 by using a conductive adhesive member. One end of the circuit board 300 may be an opposite end of the other end of the circuit board 300.

The timing control circuit 400 may receive digital video data and timing signals received from the outside. The timing control circuit 400 may generate the scan timing control signal SCS, the emission timing control signal ECS, and the data timing control signal DCS for controlling the display panel 100 in response to the timing signals. The timing control circuit 400 may output the scan timing control signal SCS to the scan driver 610, and output the emission timing control signal ECS to the emission driver 620. The timing control circuit 400 may output the digital video data and the data timing control signal DCS to the data driver 700.

The power supply circuit 500 may generate a plurality of panel driving voltages based on a power voltage from the outside. For example, the power supply circuit 500 may generate a first driving voltage VSS, a second driving voltage VDD, and a third driving voltage VINT and supply them to the display panel 100. The first driving voltage VSS, the second driving voltage VDD, and the third driving voltage VINT may be described in greater detail infra in conjunction with FIG. 3.

Each of the timing control circuit 400 and the power supply circuit 500 may be formed as an integrated circuit (IC) and may be attached to substantially the same surface of the circuit board 300. In this case, the scan timing control signal SCS, the emission timing control signal ECS, the digital video data signal DATA, and the data timing control signal DCS of the timing control circuit 400 may be supplied to the display panel 100 through the circuit board 300. Further, the first driving voltage VSS, the second driving voltage VDD, and the third driving voltage VINT of the power supply circuit 500 may be supplied to the display panel 100 through the circuit board 300.

Alternatively, each of the timing control circuit 400 and the power supply circuit 500 may be located in the non-display area NDA of the display panel 100, similarly to the scan driver 610, the emission driver 620, and the data driver 700. In this case, the timing control circuit 400 may include a plurality of timing transistors, and each power supply circuit 500 may include a plurality of power transistors. The plurality of timing transistors and the plurality of power transistors may be formed on the semiconductor substrate SSUB, such as shown in FIG. 7, described infra, through a semiconductor process. For example, the plurality of timing transistors and the plurality of power transistors may be formed as CMOS transistors, but embodiments of the present disclosure is not necessarily limited thereto. Each of the timing control circuit 400 and the power supply circuit 500 may be located between the data driver 700 and the first pad portion PDA1, such as shown in FIG. 4, described infra.

FIG. 3 shows a first sub-pixel according to an embodiment, indicated generally by the reference indicator SP1.

Referring to FIG. 3, the first sub-pixel SP1 may be connected to the write scan line GWL, the control scan line GCL, the bias scan line GBL, the first emission control line ECL1, the second emission control line ECL2, and the data line DL. Further, the first sub-pixel SP1 may be connected to a first driving voltage line VSL to which the first driving voltage VSS corresponding to a low potential voltage is applied, a second driving voltage line VDL to which the second driving voltage VDD corresponding to a high potential voltage is applied, and a third driving voltage line VIL to which the third driving voltage VINT corresponding to an initialization voltage is applied.

The first sub-pixel SP1 includes a plurality of transistors T1 to T6, a light-emitting element LE, a first capacitor CP1, and a second capacitor CP2.

The light-emitting element LE emits light in response to a driving current Ids flowing through the channel of the first transistor T1. The emission amount of the light-emitting element LE may be proportional to the driving current Ids. The first electrode of the light-emitting element LE may be an anode electrode, and the second electrode of the light-emitting element LE may be a cathode electrode. The light-emitting element LE may be an organic light-emitting diode including a first electrode, a second electrode, and an organic light-emitting layer located between the first electrode and the second electrode, but embodiments of the present disclosure is not necessarily limited thereto. For example, the light-emitting element LE may be an inorganic light-emitting element including a first electrode, a second electrode, and an inorganic semiconductor located between the first electrode and the second electrode, in which case the light-emitting element LE may be a micro light-emitting diode.

The first transistor T1 may be a driving transistor that controls a source-drain current Ids (hereinafter referred to as “driving current”) flowing between the source electrode and the drain electrode based on a voltage applied to the gate electrode.

A second transistor T2 may be located between one electrode of the first capacitor CP1 and the data line DL. The second transistor T2 is turned on by the write scan signal of the write scan line GWL to connect the one electrode of the first capacitor CP1 to the data line DL. Accordingly, the data voltage of the data line DL may be applied to the one electrode of the first capacitor CP1.

A third transistor T3 may be located between a first node N1 and a second node N2. The third transistor T3 is turned on by the write control signal of the control scan line GCL to connect the first node N1 to the second node N2. For example, when the gate electrode and the source electrode of the first transistor T1 are connected, the first transistor T1 may operate like a diode.

The fourth transistor T4 may be connected between the second node N2 and a third node N3. The fourth transistor T4 is turned on by the first emission control signal of the first emission control line ECL1 to connect the second node N2 to the third node N3. Accordingly, the driving current of the first transistor T1 may be supplied to the light-emitting element LE. A fifth transistor T5 may be located between the third node N3 and the third driving voltage line VIL. The fifth transistor T5 is turned on by the bias scan signal of the bias scan line bias scan line GBL to connect the third node N3 to the third driving voltage line VIL. Accordingly, the third driving voltage VINT of the third driving voltage line VIL may be applied to the first electrode of the light-emitting element LE.

The sixth transistor T6 may be located between the source electrode of the first transistor T1 and the second driving voltage line VDL. The sixth transistor T6 may be turned on by the second emission control signal of the second emission control line ECL2 to connect the source electrode of the first transistor T1 to the second driving voltage line VDL. Accordingly, the second driving voltage VDD of the second driving voltage line VDL may be applied to the source electrode of the first transistor T1.

The first capacitor CP1 is formed between the first node N1 and the drain electrode of the second transistor T2. The second capacitor CP2 is formed between the gate electrode of the first transistor T1 and the second driving voltage line VDL.

Each of the first to sixth transistors T1 to T6 may be a metal-oxide-semiconductor field effect transistor (MOSFET). For example, each of the first to sixth transistors T1 to T6 may be a p-type MOSFET, but embodiments of the present disclosure is not necessarily limited thereto. Each of the first to sixth transistors T1 to T6 may be an n-type MOSFET. Alternatively, some of the first to sixth transistors T1 to T6 may be p-type MOSFETs, and each of the remaining transistors may be an n-type MOSFET.

Although it is illustrated in FIG. 3 that the first sub-pixel SP1 includes six transistors T1 to T6 and two capacitors CP1 and CP2, it should be noted that the equivalent circuit diagram of the first sub-pixel SP1 is not necessarily limited to that shown in FIG. 3. For example, the number of transistors and the number of capacitors of the first sub-pixel SP1 are not necessarily limited to those shown in FIG. 3.

Further, the equivalent circuit diagram of the second sub-pixel SP2 and the equivalent circuit diagram of the third sub-pixel SP3 may be substantially the same as the equivalent circuit diagram of the first sub-pixel SP1 described in conjunction with FIG. 3. Therefore, the description of the equivalent circuit diagram of the second sub-pixel SP2 and the equivalent circuit diagram of the third sub-pixel SP3 need not be repeated in the present disclosure.

FIG. 4 shows an example of a display panel according to an embodiment, indicated generally by the reference indicator 100a.

Referring to FIG. 4, the display area DAA of the display panel 100a according to an embodiment includes the plurality of pixels PX arranged in a matrix form. The non-display area NDA of the display panel 100a according to an embodiment includes the scan driver 610, the emission driver 620, the data driver 700, a first distribution circuit 710, a second distribution circuit 720, the first pad portion PDA1, and a second pad portion PDA2.

The scan driver 610 may be located on a first side of the display area DAA, and the emission driver 620 may be located on a second side of the display area DAA. For example, the scan driver 610 may be located on one side of the display area DAA in the first direction DR1, and the emission driver 620 may be located on the other side of the display area DAA in the first direction DR1. However, embodiments of the present disclosure is not necessarily limited thereto, and the scan driver 610 and the emission driver 620 may be located on both the first side and the second side of the display area DAA.

The first pad portion PDA1 may include the plurality of first pads PD1 connected to pads or bumps of the circuit board 300 through a conductive adhesive member. The first pad portion PDA1 may be located on a third side of the display area DAA. For example, the first pad portion PDA1 may be located on one side of the display area DAA in the second direction DR2. Moreover, the first pad portion PDA1 may be located outside the data driver 700 in the second direction DR2.

The second pad portion PDA2 may include a plurality of second pads PD2 corresponding to inspection pads that test whether the display panel 100a operates normally. The plurality of second pads PD2 may be connected to a jig or a probe pin during an inspection process, or may be connected to a circuit board for inspection. The circuit board for inspection may be a printed circuit board including a rigid material or a flexible printed circuit board including a flexible material.

The second pad portion PDA2 may be located on a fourth side of the display area DAA. For example, the second pad portion PDA2 may be located on the other side of the display area DAA in the second direction DR2 opposite to the first pad portion PDA1. The second pad portion PDA2 may be located outside the second distribution circuit 720 in the second direction DR2.

The first distribution circuit 710 distributes data voltages applied through the first pad portion PDA1 to the plurality of data lines DL. For example, the first distribution circuit 710 may distribute the data voltages applied through one first pad PD1 of the first pad portion PDA1 to the P (P is a positive integer of 2 or more) data lines DL, and as a result, the number of the plurality of first pads PD1 may be minimized. The first distribution circuit 710 may be located on the third side of the display area DAA of the display panel 100a. For example, the first distribution circuit 710 may be located on one side of the display area DAA in the second direction DR2.

The second distribution circuit 720 distributes signals applied through the second pad portion PDA2 to the scan driver 610, the emission driver 620, and the data lines DL. The second pad portion PDA2 and the second distribution circuit 720 may be configured to inspect the operation of each of the pixels PX in the display area DAA. The second distribution circuit 720 may be located on the fourth side of the display area DAA of the display panel 100a. For example, the second distribution circuit 720 may be located on the other side of the display area DAA in the second direction DR2.

A cathode connection portion CCA may be a region in which a second electrode CAT, such as shown in FIG. 7, described infra, of a display element layer EML, such as shown in FIG. 7, described infra, is connected to the first driving voltage line VSL of the non-display area NDA. The cathode connection portion CCA may be located outside at least one side of the display area DAA. For example, the cathode connection portion CCA may be located outside at least on one side among the left side, the right side, the upper side, and the lower side of the display area DAA. Alternatively, the cathode connection portion CCA may be located to surround the display area DAA as shown in FIG. 4 in order to minimize a deviation in the first driving voltage VSS such as due to a voltage drop (IR decrease) or voltage rise (IR increase) of the second electrode CAT in the display area DAA.

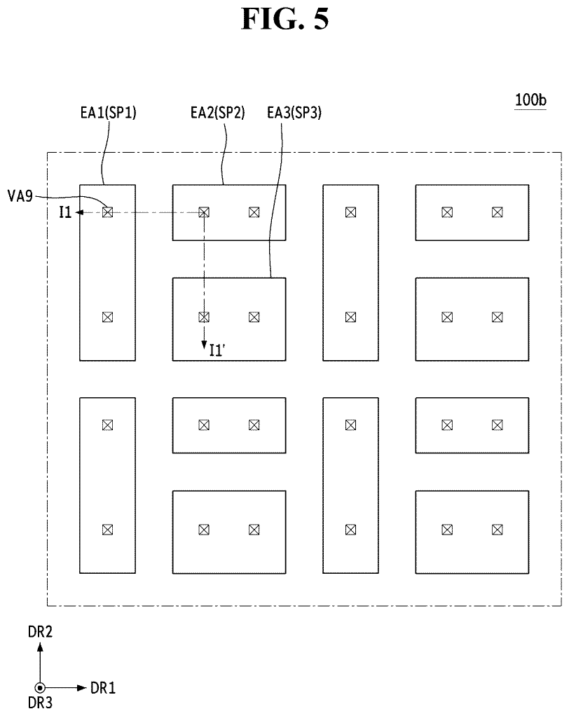

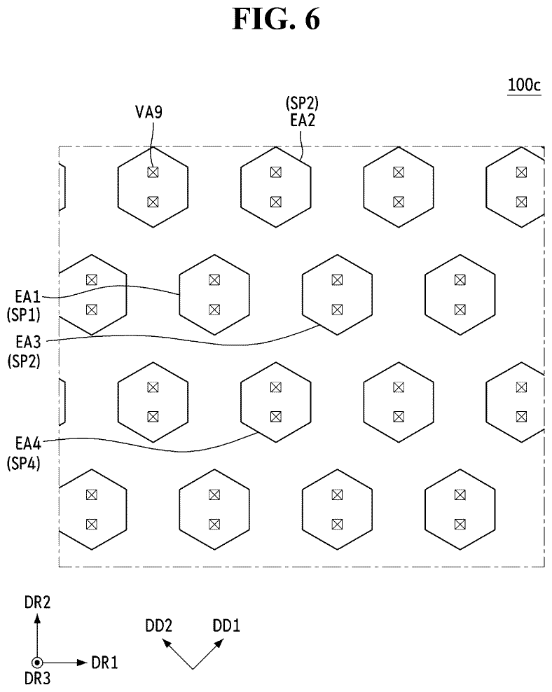

FIG. 5 shows an example of the display area of FIG. 4, indicated generally by the reference indicator 100b. FIG. 6 shows another example of the display area of FIG. 4, indicated generally by the reference indicator 100c.

Referring to FIGS. 5 and 6, each of the pixels PX includes the first emission area EA1 that is an emission area of the first sub-pixel SP1, the second emission area EA2 that is an emission area of the second sub-pixel SP2, and the third emission area EA3 that is an emission area of the third sub-pixel SP3.

The first emission area EA1, the second emission area EA2, and the third emission area EA3 may have, in plan view, a quadrilateral or hexagonal shape as shown in FIGS. 5 and 6, but the present disclosure is not necessarily limited thereto. The first emission area EA1, the second emission area EA2, and the third emission area EA3 may have a polygonal shape other than a quadrangle or hexagon, a circular shape, an elliptical shape, or an atypical shape in plan view.

As shown in FIG. 5, in each of the plurality of pixels PX, the first emission area EA1 and the second emission area EA2 may be adjacent to each other in the first direction DR1. Further, the first emission area EA1 and the third emission area EA3 may be adjacent to each other in the first direction DR1. In addition, the second emission area EA2 and the third emission area EA3 may be adjacent to each other in the second direction DR2. The area of the first emission area EA1, the area of the second emission area EA2, and the area of the third emission area EA3 may be different.

Alternatively, as shown in FIG. 6, the emission areas EA1, EA2, EA3, and EA4 may have a hexagonal shape in plan view. In this case, the first emission area EA1 and the third emission area EA3 may be adjacent in the first direction DR1, and the second emission area EA2 and the fourth emission area EA4 may be adjacent in the second direction DR2. Additionally, the first emission area EA1 and the second emission area EA2 may be adjacent in a first diagonal direction DD1, and the second emission area EA2 and the third emission area EA3 may be adjacent in a second diagonal direction DD2. Additionally, the first emission area EA1 and the fourth emission area EA4 may be adjacent in the second diagonal direction DD2, and the third emission area EA3 and the fourth emission area EA4 may be adjacent in the first diagonal direction DD1. The first diagonal direction DD1 may be a direction between the first direction DR1 and the second direction DR2, and may refer to a direction inclined by about 45 degrees with respect to the first direction DR1 and the second direction DR2, and the second diagonal direction DD2 may be a direction perpendicular to the first diagonal direction DD1.

The first sub-pixel SP1 may emit first light, the second sub-pixel SP2 may emit second light, and the third sub-pixel SP3 may emit third light. Here, the first light may be light of a blue wavelength band, the second light may be light of a green wavelength band, and the third light may be light of a red wavelength band. For example, the blue wavelength band may be a wavelength band of light whose main peak wavelength is in the range of approximately 450 nm to approximately 470 nm, the green wavelength band may be a wavelength band of light whose main peak wavelength is in the range of approximately 515 nm to approximately 535 nm, and the red wavelength band may be a wavelength band of light whose main peak wavelength is in the range of approximately 620 nm to approximately 640 nm.

The wavelength band of the main peak wavelength is based on the full width at half maximum (FWHM) of the main peak wavelength. For example, the blue wavelength band may have a full width at half maximum of the main peak wavelength of the light of approximately 20 nm to approximately 30 nm, the green wavelength band may have a full width at half maximum of the main peak wavelength of the light of approximately 30 nm to approximately 40 nm, and the red wavelength band may have a full width at half maximum of the main peak wavelength of the light of approximately 30 nm to approximately 40 nm.

Each of the plurality of pixels PX may include three emission areas EA1, EA2, and EA3 as shown in FIG. 5, or may include four emission areas EA1, EA2, EA3, and EA4 as shown in FIG. 6. In this case, the fourth emission area EA4 may emit substantially the same second light as the second emission area EA2, but the present disclosure is not necessarily limited thereto.

The emission areas of the plurality of pixels PX may be arranged in a stripe structure in which the emission areas are arranged in the first direction DR1, a PenTile® structure in which the emission areas EA1, EA2, EA3, and EA4 are arranged in a rhombus shape, or a hexagonal structure in which the emission areas each having a hexagonal shape are arranged as shown in FIG. 6.

Although display device examples with various layers and/or lenses may be shown and described, infra, by way of example for illustrative purposes, it shall be understood that some of the layers and/or lenses are optional and/or may be combined with others. A display device embodiment includes a display panel and a reflection control film located on the display panel, where a first function of a transmittance and a reflectivity of the reflection control film in respect to light of a first wavelength range is different from the first function of a transmittance and a reflectivity of the reflection control film in respect to light of a second wavelength range, and/or where a second function of the transmittance and the reflectivity of the reflection control film in respect to light of the first wavelength range is substantially the same as the second function of the transmittance and the reflectivity of the reflection control film in respect to light of the second wavelength range.

For example, the first function may be a product of transmittance and reflectivity in respect to light of a same wavelength range, and the second function may be a sum of transmittance and reflectivity in respect to light of the same wavelength range. Moreover, the first and second functions may be evaluated at one or more wavelengths in each respective wavelength range, and/or computed as an average, mean, median, total, or like representation of transmittance and reflectivity values within each of such ranges.

FIG. 7 shows an example of a display panel pixel taken along line I1-I1′ of FIG. 5, indicated generally by the reference indicator PXa.

Referring to FIG. 7, the display panel 100a includes a semiconductor backplane SBP, a light-emitting element backplane EBP, the display element layer EML, an encapsulation layer TFE, an optical layer OPL, a cover layer CVL, and a polarizing plate POL.

The semiconductor backplane SBP includes the semiconductor substrate SSUB having a plurality of pixel transistors PTR, a plurality of semiconductor insulating films covering the plurality of pixel transistors PTR, and a plurality of contact terminals CTE electrically connected to the plurality of pixel transistors PTR, respectively. The plurality of pixel transistors PTR may be the first to sixth transistors T1 to T6 described with reference to FIG. 3.

The semiconductor substrate SSUB may be a silicon substrate, a germanium substrate, or a silicon-germanium substrate. The semiconductor substrate SSUB may be a substrate doped with a first type of impurity. A plurality of well regions WA may be located on the top surface of the semiconductor substrate SSUB. The plurality of well regions WA may be regions doped with a second type of impurity. The second type of impurity may be different from the aforementioned first type of impurity. For example, when the first type of impurity is a p-type impurity, the second type of impurity may be an n-type impurity. Alternatively, when the first type of impurity is an n-type impurity, the second type of impurity may be a p-type impurity.

Each of the plurality of well regions WA includes a source region SA corresponding to the source electrode of the pixel transistor PTR, a drain region DA corresponding to the drain electrode, and a channel region CH located at least partially between the source region SA and the drain region DA.

A lower insulating film BINS may be located between a gate electrode GE and the well region WA. A side insulating film SINS may be located on the side surface of the gate electrode GE. The side insulating film SINS may be located between the lower insulating film BINS and the first semiconductor insulating film SINS1.

Each of the source region SA and the drain region DA may be a region doped with the first type of impurity. The gate electrode GE of the pixel transistor PTR may overlap the well region WA in the third direction DR3, which is the thickness direction of the semiconductor substrate SSUB. The channel region CH may overlap the gate electrode GE in the third direction DR3. The source region SA may be located on one side of the gate electrode GE, and the drain region DA may be located on the other side of the gate electrode GE.

Each of the plurality of well regions WA further includes a first low-concentration impurity region LDD1 located between the channel region CH and the source region SA, and a second low-concentration impurity region LDD2 located between the channel region CH and the drain region DA. The first low-concentration impurity region LDD1 may be a region having a lower impurity concentration than the source region SA such as due to the lower insulating film BINS. The second low-concentration impurity region LDD2 may be a region having a lower impurity concentration than the drain region DA such as due to the lower insulating film BINS. The distance between the source region SA and the drain region DA may increase such as due to the first low-concentration impurity region LDD1 and the second low-concentration impurity region LDD2, which may result in an increase of the length of the channel region CH of each of the pixel transistors PTR.

A first semiconductor insulating film SINS1 may be located on the semiconductor substrate SSUB. A second semiconductor insulating film SINS2 may be located on the first semiconductor insulating film SINS1.

The plurality of contact terminals CTE may be located on the second semiconductor insulating film SINS2, such as within a third semiconductor insulating film SINS3. Each of the plurality of contact terminals CTE may be connected to any one of the gate electrode GE, the source region SA, and the drain region DA of each of the pixel transistors PTR through a hole penetrating the first semiconductor insulating film SINS1 and the second semiconductor insulating film SINS2. The plurality of contact terminals CTE may include any one of copper (Cu), aluminum (Al), tungsten (W), molybdenum (Mo), chromium (Cr), gold (Au), titanium (Ti), nickel (Ni), and neodymium (Nd), or an alloy including any one of them.

The third semiconductor insulating film SINS3 may be located on a side surface of each of the plurality of contact terminals CTE. The top surface of each of the plurality of contact terminals CTE may be exposed without being covered by the third semiconductor insulating film SINS3.

Each of the first semiconductor insulating film SINS1, the second semiconductor insulating film SINS2, and the third semiconductor insulating film SINS3 may include silicon carbonitride (SiCN) or a silicon oxide (SiOₓ) based inorganic film, but the present disclosure is not necessarily limited thereto.

The semiconductor substrate SSUB may be replaced with a glass substrate or a polymer resin substrate such as polyimide. In this case, thin film transistors may be located on the glass substrate or the polymer resin substrate. The glass substrate may be a rigid substrate that need not bend, and the polymer resin substrate may be a flexible substrate that can be bent or curved.

The light-emitting element backplane EBP includes a plurality of conductive layers ML1 to ML8, a plurality of vias VA1 to VA9, and a plurality of insulating films INS1 to INS11. In addition, the light-emitting element backplane EBP includes a plurality of insulating films INS1 to INS9 located between the first to eighth conductive layers ML1 to ML8.

First to eighth insulating films INS1 to INS8 serve to insulate the first to eighth conductive layers ML1 to ML8. The first to eighth conductive layers ML1 to ML8 serve to connect the plurality of contact terminals CTE exposed from the semiconductor backplane SBP to thereby implement the circuit of the first sub-pixel SP1 shown in FIG. 3.

For example, the first to sixth transistors T1 to T6 may be formed in the semiconductor backplane SBP, where the connection of the first to sixth transistors T1 to T6 and the first and second capacitors CP1 and CP2 is accomplished through the first to eighth conductive layers ML1 to ML8. In addition, the connection between the drain region corresponding to the drain electrode of the fourth transistor T4, the source region corresponding to the source electrode of the fifth transistor T5, and a first electrode AND of the light-emitting element LE may also be accomplished through the first to eighth conductive layers ML1 to ML8.

The first to eighth conductive layers ML1 to ML8 and the first to eighth vias VA1 to VA8 may include substantially the same material. The first to eighth conductive layers ML1 to ML8 and the first to eighth vias VA1 to VA8 may include any one of copper (Cu), aluminum (Al), tungsten (W), molybdenum (Mo), chromium (Cr), gold (Au), titanium (Ti), nickel (Ni), and neodymium (Nd), or an alloy including any one of them. The first to eighth vias VA1 to VA8 may include substantially the same material. The first to eighth insulating films INS1 to INS8 may be formed as silicon oxide (SiOₓ) based inorganic films, but embodiments of the present disclosure is not necessarily limited thereto.

A ninth insulating film INS9 may be located on the eighth insulating film INS8 and the eighth conductive layer ML8. The ninth insulating film INS9 may be formed as a silicon oxide (SiOₓ) based inorganic film, but embodiments of the present disclosure is not necessarily limited thereto.

Each of the ninth vias VA9 may penetrate the ninth insulating film INS9 and be connected to the exposed eighth conductive layer ML8. The ninth vias VA9 may include any one of copper (Cu), aluminum (Al), tungsten (W), molybdenum (Mo), chromium (Cr), gold (Au), titanium (Ti), nickel (Ni), and neodymium (Nd), or an alloy including any one of them.

The display element layer EML may be located on the light-emitting element backplane EBP. The display element layer EML may include tenth and eleventh insulating films INS10 and INS11, a reflective electrode RL, the first electrodes AND, a light-emitting stack IL, the second electrode CAT, a pixel defining film PDL, and a plurality of trenches TRC.

The reflective electrode RL may be located on the ninth insulating film INS9. The reflective electrode RL may include at least one reflective electrode RL1, RL2, RL3, and RL4. For example, the reflective electrode RL may include first to fourth reflective electrodes RL1, RL2, RL3, and RL4 as shown in FIG. 7.

The first reflective electrodes RL1 may be located on the ninth insulating film INS9, and may be connected to the ninth via VA9. Each of the second reflective electrodes RL2 may be located on the first reflective electrode RL1 corresponding thereto. Each of the third reflective electrodes RL3 may be located on the second reflective electrode RL2 corresponding thereto. Each of the fourth reflective electrodes RL4 may be located on the third reflective electrode RL3 corresponding thereto.

Since the second reflective electrode RL2 is an electrode that substantially reflects light from the light-emitting elements LE, the thickness of the second reflective electrode RL2 may be greater than the thickness of each of the first reflective electrode RL1, the third reflective electrode RL3, and the fourth reflective electrode RL4.

The first reflective electrodes RL1 may include any one or more of copper (Cu), aluminum (Al), tungsten (W), molybdenum (Mo), chromium (Cr), gold (Au), titanium (Ti), nickel (Ni), and neodymium (Nd), or an alloy including any one or more of these. For example, the first reflective electrodes RL1 may include titanium nitride (TiN), the second reflective electrodes RL2 may include aluminum (Al), the third reflective electrodes RL3 may include titanium nitride (TiN), and the fourth reflective electrodes RL4 may include titanium (Ti).

The tenth insulating film INS10 may be located on the ninth insulating film INS9. The tenth insulating film INS10 may be located between the reflective electrodes RL that are adjacent to each other. The tenth insulating film INS10 may be a film for flattening a stepped portion caused by the reflective electrodes RL. The eleventh insulating film INS11 may be located on the tenth insulating film INS10 and the reflective electrode RL.

The tenth insulating film INS10 and the eleventh insulating film INS11 may be formed as silicon oxide (SiOₓ) based inorganic films, but embodiments of the present disclosure is not necessarily limited thereto.

The eleventh insulating film INS11 may be an optical auxiliary layer for adjusting the resonance distance of light emitted from the light-emitting stack IL in at least one of the first sub-pixel SP1, the second sub-pixel SP2, or the third sub-pixel SP3. The thickness of the eleventh insulating film INS11 may be different in the first sub-pixel SP1, the second sub-pixel SP2, and the third sub-pixel SP3. For example, in order to adjust a distance from the reflective electrode RL to the second electrode CAT based on a main wavelength of light emitted from each of the first sub-pixel SP1, the second sub-pixel SP2, and the third sub-pixel SP3, the thickness of the eleventh insulating film INS11 may be set for each of the first sub-pixel SP1, the second sub-pixel SP2, and the third sub-pixel SP3.

For example, as shown in FIG. 7, the thickness of the eleventh insulating film INS11 in the first sub-pixel SP1 may be greater than the thickness of the eleventh insulating film INS11 in the second sub-pixel SP2, and the thickness of the eleventh insulating film INS11 in the second sub-pixel SP2 may be greater than the thickness of the eleventh insulating film INS11 in the third sub-pixel SP3. In this case, the distance between the reflective electrode RL and the first electrode AND in the first sub-pixel SP1 may be greater than the distance between the reflective electrode RL and the first electrode AND in the second sub-pixel SP2. In addition, the distance between the reflective electrode RL and the first electrode AND in the second sub-pixel SP2 may be greater than the distance between the reflective electrode RL and the first electrode AND in the third sub-pixel SP3.

Each of the tenth vias VA10 may penetrate the eleventh insulating film INS11 and be connected to the exposed ninth metal layer ML9. The tenth vias VA10 may include any one of copper (Cu), aluminum (Al), tungsten (W), molybdenum (Mo), chromium (Cr), gold (Au), titanium (Ti), nickel (Ni), and neodymium (Nd), or an alloy including any one of them. The thickness of the tenth via VA10 in the first sub-pixel SP1 may be greater than the thickness of the tenth via VA10 in the second sub-pixel SP2, and the thickness of the tenth via VA10 in the second sub-pixel SP2 may be greater than the thickness of the tenth via VA10 in the third sub-pixel SP3.

The first electrode AND of each of the light-emitting elements LE may be located on the eleventh insulating film INS11 and connected to the tenth via VA10. The first electrode AND of each of the light-emitting elements LE may be connected to the drain region DA or source region SA of the pixel transistor PTR through the tenth via VA10, the reflective electrode RL, the first to ninth vias VA1 to VA9, the first to eighth metal layers ML1 to ML8, and the contact terminal CTE. The first electrode AND of each of the light-emitting elements LE may include any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the first electrode AND of each of the light-emitting elements LE may be titanium nitride (TiN).

The pixel defining film PDL may be located on a part of the first electrode AND of each of the light-emitting elements LE. The pixel defining film PDL may overlap the edge of the first electrode AND of each of the light-emitting elements LE. The pixel defining film PDL may partition the first emission areas EA1, the second emission areas EA2, and the third emission areas EA3. Each of the first emission area EA1, the second emission area EA2, and the third emission area EA3 may be an area where the light-emitting element LE including the first electrode AND, the light-emitting stack IL, and the second electrode CAT is located.

The first emission area EA1 may be defined as an area in which the first electrode AND, the light-emitting stack IL, and the second electrode CAT are sequentially stacked in the first sub-pixel SP1 to emit light. The second emission area EA2 may be defined as an area in which the first electrode AND, the light-emitting stack IL, and the second electrode CAT are sequentially stacked in the second sub-pixel SP2 to emit light. The third emission area EA3 may be defined as an area in which the first electrode AND, the light-emitting stack IL, and the second electrode CAT are sequentially stacked in the third sub-pixel SP3 to emit light.

The pixel defining film PDL may include first to third pixel defining films PDL1, PDL2, and PDL3. The first pixel defining film PDL1 may be located on the edge of the first electrode AND of each of the light-emitting elements LE, the second pixel defining film PDL2 may be located on the first pixel defining film PDL1, and the third pixel defining film PDL3 may be located on the second pixel defining film PDL2. The first pixel defining film PDL1, the second pixel defining film PDL2, and the third pixel defining film PDL3 may be formed as silicon oxide (SiOₓ) based inorganic films. Alternatively, the first pixel defining film PDL1 and the third pixel defining film PDL3 may be formed as silicon nitride (SiNₓ) based inorganic films, whereas the second pixel defining film PDL2 may be formed as a silicon oxide (SiOₓ) based inorganic film. The first pixel defining film PDL1, the second pixel defining film PDL2, and the third pixel defining film PDL3 may each have a thickness of about 500 Å.

In order to reduce or prevent the likelihood of the first encapsulation inorganic film TFE1 being cut off such as due to the step coverage, the first pixel defining film PDL1, the second pixel defining film PDL2, and the third pixel defining film PDL3 may have a cross-sectional structure having a stepped portion. Step coverage refers to the ratio of the degree of thin film coated on an inclined portion to the degree of thin film coated on a flat portion. The lower the step coverage, the more likely it is that the thin film may be cut off at inclined portions.

Each of the plurality of trenches TRC may penetrate the first pixel defining film PDL1, the second pixel defining film PDL2, and the third pixel defining film PDL3. The eleventh insulating film INS11 may be at least partially recessed at each of the plurality of trenches TRC.

At least one trench TRC may be located between the neighboring sub-pixels SP1, SP2, and SP3. Although FIG. 7 illustrates that two trenches TRC are located between the neighboring sub-pixels SP1, SP2, and SP3, the present disclosure is not necessarily limited thereto.

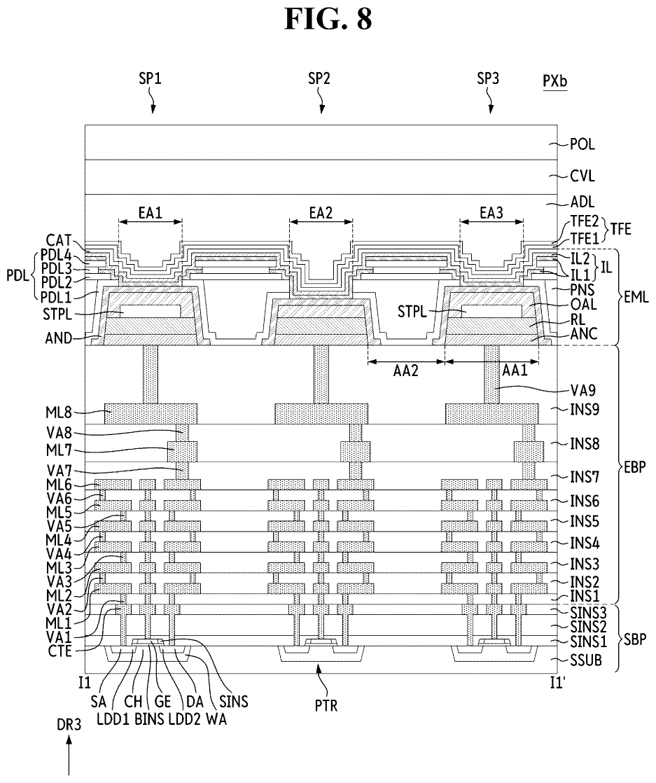

The light-emitting stack IL may include a plurality of stack layers IL1, IL2, and IL3. FIG. 7 illustrates that the light-emitting stack IL has a three-tandem structure including a first stack layer IL1, a second stack layer IL2, and a third stack layer IL3, but the present disclosure is not necessarily limited thereto. For example, the light-emitting stack IL may have a two-tandem structure including two stack layers as shown in FIG. 8, described infra.

In the three-tandem structure, the light-emitting stack IL may have a tandem structure including a plurality of stack layers IL1, IL2, and IL3 that emit different lights. For example, the light-emitting stack IL may include the first stack layer IL1 that emits the first light, the second stack layer IL2 that emits the second light, and the third stack layer IL3 that emits the third light. The first stack layer IL1, the second stack layer IL2, and the third stack layer IL3 may be sequentially stacked.

The first stack layer IL1 may have a structure in which a first hole transport layer, a first light-emitting layer that emits the first light, and a first electron transport layer are sequentially stacked. The second stack layer IL2 may have a structure in which a second hole transport layer, a second light-emitting layer that emits the second light, and a second electron transport layer are sequentially stacked. The third stack layer IL3 may have a structure in which a third hole transport layer, a third light-emitting layer that emits the third light, and a third electron transport layer are sequentially stacked.

A first charge generation layer for supplying charges or electron valance holes to the second stack layer IL2 and supplying electrons to the first stack layer IL1 may be located between the first stack layer IL1 and the second stack layer IL2. The first charge generation layer may include an n-type charge generation layer that supplies electrons to the first stack layer IL1 and a p-type charge generation layer that supplies holes to the second stack layer IL2. The n-type charge generation layer may include a dopant of a metal material.

A second charge generation layer for supplying charges or electron valance holes to the third stack layer IL3 and supplying electrons to the second stack layer IL2 may be located between the second stack layer IL2 and the third stack layer IL3. The second charge generation layer may include an n-type charge generation layer that supplies electrons to the second stack layer IL2 and a p-type charge generation layer that supplies holes to the third stack layer IL3.

The first stack layer IL1 may be located on the pixel defining film PDL and the first electrodes AND, and a residual film RIL located on the bottom surface of each trench TRC may be substantially the same material as the first stack layer IL1. For example, due to the trench TRC, the first stack layer IL1 may be cut off between the neighboring sub-pixels SP1, SP2, and SP3. The second stack layer IL2 may be located on the first stack layer IL1. For example, due to the trench TRC, the second stack layer IL2 may be cut off between the neighboring sub-pixels SP1, SP2, and SP3. A cavity or empty space ESS may be located between the residual film RIL and the second stack layer IL2 in the trench TRC. The third stack layer IL3 may be located on the second stack layer IL2. The third stack layer IL3 need not be cut off by the trench TRC and may be located to cover the second stack layer IL2 in each of the trenches TRC.

In the three-tandem structure, each of the plurality of trenches TRC may be a structure for cutting off the first to third hole transport layers, the first charge generation layer, and the second charge generation layer of the first to third stack layers IL1, IL2, and IL3 of the display element layer EML disposed between the neighboring sub-pixels SP1, SP2, and SP3. In addition, in the two-tandem structure, each of the plurality of trenches TRC may be a structure for cutting off the charge generation layer and the lower stack layer located between the lower stack layer and the upper stack layer.

In order to stably cut off the first and second stack layers IL1 and IL2 of the display element layer EML disposed between the neighboring sub-pixels SP1, SP2, and SP3, the height of each of the plurality of trenches TRC may be greater than the height of the pixel defining film PDL. The height of each of the plurality of trenches TRC refers to the length of each of the plurality of trenches TRC in the third direction DR3. The height of the pixel defining film PDL refers to the length of the pixel defining film PDL in the third direction DR3. In order to cut off the charge generation layers and the hole transport layers of the light-emitting stack IL of the display element layer EML disposed between the neighboring sub-pixels SP1, SP2, and SP3, a different structure may be present instead of the trench TRC. For example, instead of the trench TRC, a reverse tapered partition wall may be located on the pixel defining film PDL.

In addition, FIG. 7 illustrates that the light-emitting stack IL that emits light is located in the first emission area EA1, the second emission area EA2, and the third emission area EA3, but the present disclosure is not necessarily limited thereto. For example, instead of the light-emitting stack IL, the first light-emitting layer may be located in the first emission area EA1, and may be omitted from the second emission area EA2 and the third emission area EA3. Furthermore, the second light-emitting layer may be located in the second emission area EA2 and may be omitted from the first emission area EA1 and the third emission area EA3. Furthermore, the third light-emitting layer may be located in the third emission area EA3 and may be omitted from the first emission area EA1 and the second emission area EA2. In this case, first to third color filters CF1, CF2, and CF3 of the optical layer OPL may be omitted.

The second electrode CAT may be located on the light-emitting stack IL. The second electrode CAT may be located on the third stack layer IL3 in each of the plurality of trenches TRC. The second electrode CAT may include a transparent conductive material (TCO) such as ITO or IZO that can transmit light or a semi-transmissive conductive material such as magnesium (Mg), silver (Ag), or an alloy of magnesium (Mg) and silver (Ag). When the second electrode CAT includes a semi-transmissive conductive material, the light emission efficiency may be optimized in each of the first to third sub-pixels SP1, SP2, and SP3 such as due to a micro-cavity effect.

The encapsulation layer TFE may be located on the display element layer EML. The encapsulation layer TFE may include at least one inorganic film TFE1 and TFE2 to reduce or prevent oxygen or moisture from permeating into the display element layer EML. The first encapsulation inorganic film TFE1 may be located on the second electrode CAT, and the second encapsulation inorganic film TFE2 may be located on the first encapsulation inorganic film TFE1. The first encapsulation inorganic film TFE1 and the second encapsulation inorganic film TFE2 may be formed as multiple films in which one or more inorganic films of silicon nitride (SiNₓ), silicon oxynitride (SiOₓN_{y}), silicon oxide (SiOₓ), titanium oxide (TiOₓ), and aluminum oxide (AlOₓ) layers are alternately stacked.

In addition, the encapsulation layer TFE may include at least one organic film TFE3 to protect the display element layer EML from foreign substances such as dust. The at least one organic film of the encapsulation layer TFE may be located between the first encapsulation inorganic film TFE1 and the second encapsulation inorganic film TFE2. The at least one organic film TFE3 of the encapsulation layer TFE may be a monomer. Alternatively, at least one organic film TFE3 of the encapsulation layer TFE may be an organic film such as acryl resin, epoxy resin, phenolic resin, polyamide resin, polyimide resin or the like.

An adhesive layer ADL may be included as a layer for bonding the encapsulation layer TFE to the optical layer OPL. The adhesive layer ADL may be a double-sided adhesive member. In addition, the adhesive layer ADL may be a transparent adhesive member such as a transparent adhesive or a transparent adhesive resin.

The optical layer OPL includes a plurality of color filters CF1, CF2, and CF3, a plurality of lenses LNS, and a filling layer FIL. The plurality of color filters CF1, CF2, and CF3 may include the first to third color filters CF1, CF2, and CF3. The first to third color filters CF1, CF2, and CF3 may be located on the adhesive layer ADL.

The first color filter CF1 may overlap the first emission area EA1 of the first sub-pixel SP1. The first color filter CF1 may transmit light of a first color, such as light of a blue wavelength band. Thus, the first color filter CF1 may transmit light of the first color among light emitted from the first emission area EA1.

The second color filter CF2 may overlap the second emission area EA2 of the second sub-pixel SP2. The second color filter CF2 may transmit light of a second color, such as light of a green wavelength band. Thus, the second color filter CF2 may transmit light of the second color among light emitted from the second emission area EA2.

The third color filter CF3 may overlap the third emission area EA3 of the third sub-pixel SP3. The third color filter CF3 may transmit light of a third color, such as light of a red wavelength band. Thus, the third color filter CF3 may transmit light of the third color among light emitted from the third emission area EA3.

The plurality of lenses LNS may be located on the first color filter CF1, the second color filter CF2, and the third color filter CF3, respectively. Each of the plurality of lenses LNS may be a structure for increasing the proportion of light directed to the front of the display device 10a. Each of the plurality of lenses LNS may have a cross-sectional shape that is convex in an upward direction. In an embodiment, the plurality of lenses LNS may be micro lens array.

The filling layer FIL may be located on the plurality of lenses LNS. The filling layer FIL may have a selected refractive index for light to travel in the third direction DR3 at an interface between the filling layer FIL and the plurality of lenses LNS. Further, the filling layer FIL may be a planarization layer. The filling layer FIL may be an organic film such as acrylic resin, epoxy resin, phenolic resin, polyamide resin, or polyimide resin.

The cover layer CVL may be located on the filling layer FIL. The cover layer CVL may be a glass substrate or a polymer resin. When the cover layer CVL is a glass substrate, it may be attached onto the filling layer FIL. Here, the filling layer FIL may serve to bond the cover layer CVL. When the cover layer CVL is a glass substrate, it may serve as an encapsulation substrate. When the cover layer CVL is a polymer resin, it may be directly applied onto the filling layer FIL.

The polarizing plate POL may be located on one surface of the cover layer CVL. The polarizing plate POL may be a structure for reducing or preventing visibility degradation caused by reflection of external light. The polarizing plate POL may include a linear polarizing plate and a phase retardation film. For example, the phase retardation film may be a λ/4 plate (quarter-wave plate), but embodiments of the present disclosure is not necessarily limited thereto. However, when visibility degradation caused by reflection of external light is sufficiently overcome by the first to third color filters CF1, CF2, and CF3, the polarizing plate POL may be omitted.

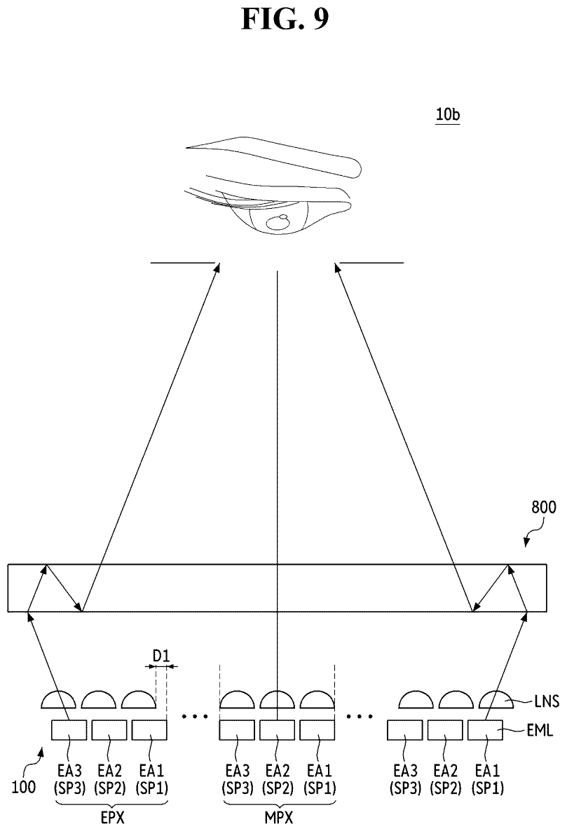

The drawing illustrates that the polarizing plate POL is mounted on the display panel 100a, but the present disclosure is not necessarily limited thereto. For example, the polarizing plate POL may be included in the optical module 800, such as shown in FIG. 9, described in greater detail infra, and in this case, the polarizing plate POL may have substantially the same components as a first optical module 810, such as shown in FIG. 9, described infra, of the optical module 800, such as also shown in FIG. 9, described infra. For example, the polarizing plate POL may be provided by being mounted on the display panel 100a or may be provided by being mounted on the optical module 800, such as shown in FIG. 9, described infra.

FIG. 8 shows still another example of a display panel pixel taken along line I1-I1′ of FIG. 5, indicated generally by the reference indicator PXb.

The embodiment of FIG. 8 differs from the embodiment of FIG. 7 in that the first electrode AND of each of the light-emitting elements LE is in contact with and electrically connected to the side surface of a connection electrode ANC connected to the eighth conductive layer ML8. The embodiment of FIG. 8 also differs from the embodiment of FIG. 7 in that the trench TRC is omitted, and instead, the third pixel defining film PDL3 and a fourth pixel defining film PDL4 have an eaves-shaped or mushroom-shaped cross-sectional structure. In the embodiment of FIG. 8, redundant description of parts already described in the embodiment of FIG. 7 may be omitted.

Referring to FIG. 8, the plurality of connection electrodes ANC may be respectively located on first portions AA1 of the ninth insulating film INS9. Each of the plurality of connection electrodes ANC may be located on the first portion AA1 of the ninth insulating film INS9 corresponding thereto. A plurality of connection electrodes ANC may include any one of copper (Cu), aluminum (Al), tungsten (W), molybdenum (Mo), chromium (Cr), gold (Au), titanium (Ti), nickel (Ni), and neodymium (Nd), an alloy including any one of them, or a transparent conductive oxide. For example, the plurality of connection electrodes ANC may include titanium (Ti), titanium nitride (TiN), indium tin oxide (ITO), or indium zinc oxide (IZO), but the present disclosure is necessarily limited thereto.

A plurality of reflective electrodes RL may be located on the plurality of connection electrodes ANC, respectively. Each of the plurality of reflective electrodes RL may be located on the connection electrode ANC corresponding thereto. The plurality of reflective electrodes RL may include any one of copper (Cu), aluminum (Al), tungsten (W), molybdenum (Mo), chromium (Cr), gold (Au), titanium (Ti), nickel (Ni), and neodymium (Nd), or an alloy including any one of them. For example, each of the plurality of reflective electrodes RL may include aluminum (Al) having high reflectivity.

A plurality of optical auxiliary films OAL may be respectively located on the plurality of reflective electrodes RL. Each of the plurality of optical auxiliary films OAL may be located on the reflective electrode RL corresponding thereto. The plurality of optical auxiliary films OAL may be formed as silicon oxide (SiOₓ) based inorganic films, but the present disclosure is not necessarily limited thereto.

In each of the first emission area EA1 and the third emission area EA3, a step layer STPL may be located on the reflective electrode RL, and the optical auxiliary film OAL may be located on the step layer STPL. In the second emission area EA2, only the optical auxiliary film OAL may be located on the reflective electrode RL. The thicknesses of the optical auxiliary film OAL may be substantially the same in the first emission area EA1, the second emission area EA2, and the third emission area EA3.

For example, due to the step layer STPL, the distance between the reflective electrode RL and the first electrode AND in the first emission area EA1 and the third emission area EA3 may be greater than the distance between the reflective electrode RL and the first electrode AND in the second emission area EA2. The thickness of the step layer STPL and the thickness of the optical auxiliary film OAL may be set in consideration of the wavelength and resonance distance of light emitted from the first stack layer IL1 of the light-emitting stack IL, and the wavelength and resonance distance of light emitted from the second stack layer IL2.

Each of the light-emitting elements LE may include the first electrode AND, the light-emitting stack IL, and the second electrode CAT.

The first electrode AND of each of the light-emitting elements LE may be located on the optical auxiliary film OAL corresponding thereto. Since the connection electrode ANC, the reflective electrode RL, and the optical auxiliary film OAL are sequentially stacked, the first electrode AND of each of the light-emitting elements LE may be located on the top surface and the side surface of the optical auxiliary film OAL, the side surface of the reflective electrode RL, and the side surface of the connection electrode ANC. Accordingly, the first electrode AND of each of the light-emitting elements LE may be in contact with and electrically connected to the side surface of the reflective electrode RL and the side surface of the connection electrode ANC. Therefore, compared to when the first electrode AND of each of the light-emitting elements LE is connected to the reflective electrode RL exposed through a through hole penetrating the optical auxiliary film OAL, the number of mask processes may be minimized, thereby advantageously lowering manufacturing cost and increasing manufacturing efficiency.

The first electrode AND of each of the light-emitting elements LE may be connected to the drain region DA or the source region SA of the pixel transistor PTR through the connection electrode ANC, the first to ninth vias VA1 to VA9, the first to eighth conductive layers ML1 to ML8, and the contact terminal CTE.

The ninth insulating film INS9 may include the first portion AA1, which overlaps the connection electrode ANC in the third direction DR3, and a second portion AA2, which need not overlap the connection electrode ANC in the third direction DR3. The thickness of the first portion AA1 and the thickness of the second portion AA2 of the ninth insulating film INS9 may be substantially the same.

Alternatively, the thickness of the first portion AA1 of the ninth insulating film INS9 may be greater than the thickness of the second portion AA2. In this case, the side surface of the first portion AA1 of the ninth insulating film INS9 may be exposed, and the first electrode AND of each of the light-emitting elements LE may be located on the exposed side surface of the first portion AA1 of the ninth insulating film INS9.

The first electrode AND of each of the light-emitting elements LE may include any one of copper (Cu), aluminum (Al), tungsten (W), molybdenum (Mo), chromium (Cr), gold (Au), titanium (Ti), nickel (Ni), and neodymium (Nd), an alloy including any one of them, or a transparent conductive oxide. For example, the first electrode AND of each of the light-emitting elements LE may include titanium (Ti), titanium nitride (TiN), indium tin oxide (ITO), or indium zinc oxide (IZO), but embodiments of the present disclosure is necessarily limited thereto.

The pixel defining film PDL may be located on a part of the first electrode AND of each of the light-emitting elements LE. The pixel defining film PDL may overlap the edge of the first electrode AND of each of the light-emitting elements LE. The pixel defining film PDL may partition the first emission areas EA1, the second emission areas EA2, and the third emission areas EA3.

The pixel defining film PDL may include first to fourth pixel defining films PDL1, PDL2, PDL3, and PDL4.

The first pixel defining film PDL1 may be located on the first electrode AND of each of the light-emitting elements LE. Specifically, the first pixel defining film PDL1 may overlap a part of the top surface of the first electrode AND located on the optical auxiliary film OAL. Further, the first pixel defining film PDL1 may overlap the first electrode AND located on the side surface of the connection electrode ANC, the side surface of the reflective electrode RL, and the side surface of the optical auxiliary film OAL. The first pixel defining film PDL1 may be located on the top surface of the second portion AA2 of the ninth insulating film INS9.

A planarization film PNS may be applied as a film for flattening the stepped portion caused by the connection electrode ANC, the reflective electrode RL, and the optical auxiliary film OAL.

The planarization film PNS may be located on the first pixel defining film PDL1 overlapping the first electrode AND located on the side surface of the connection electrode ANC, the side surface of the reflective electrode RL, and the side surface of the optical auxiliary film OAL. The planarization film PNS may be located on the first pixel defining film PDL1 located on the second portion AA2 of the ninth insulating film INS9.

The planarization film PNS may be located between the portions of first pixel defining film PDL1 adjacent in the first direction DR1 and/or the second direction DR2. The planarization film PNS may be located between the reflective electrodes RL adjacent in the first direction DR1 or the second direction DR2. The planarization film PNS may be located between the optical auxiliary films OAL adjacent in the first direction DR1 or the second direction DR2.

The step layer STPL need not be present in the second emission area EA2, whereas the step layer STPL is present in each of the first emission area EA1 and the third emission area EA3. Accordingly, the height of the connection electrode ANC, the reflective electrode RL, and the optical auxiliary film OAL in the second emission area EA2 may be less than the height of the connection electrode ANC, the reflective electrode RL, the step layer STPL, and the optical auxiliary film OAL in the first emission area EA1 and in the third emission area EA3. Therefore, the planarization film PNS may cover the top surface of the first pixel defining film PDL1 located on the top surface of the first electrode AND located in the second emission area EA2.

In contrast, the top surface of the planarization film PNS may be flatly connected to the top surface of the first pixel defining film PDL1 located on the top surface of the first electrode AND located in the first emission area EA1 and the third emission area EA3. For example, the planarization film PNS need not cover the top surface of the first pixel defining film PDL1 located on the top surface of the first electrode AND located in each of the first emission area EA1 and the third emission area EA3.

The second pixel defining film PDL2 may be located on the first pixel defining film PDL1 and the planarization film PNS, the third pixel defining film PDL3 may be located on the second pixel defining film PDL2, and the fourth pixel defining film PDL4 may be located on the third pixel defining film PDL3. The first pixel defining film PDL1 and the third pixel defining film PDL3 may be formed as silicon nitride (SiNₓ) based inorganic films, whereas the second pixel defining film PDL2, the fourth pixel defining film PDL4, and the planarization film PNS may be formed as silicon oxide (SiOₓ) based inorganic films. The first pixel defining film PDL1 includes a material different from that of the planarization film PNS, and thus may serve as a stopper in a chemical mechanical polishing process for the planarization film PNS.

When the planarization film PNS and the second pixel defining film PDL2 are both formed as silicon oxide (SiOₓ) based inorganic films, the planarization film PNS and the second pixel defining film PDL2 may be formed as a single film.

Since the length of the third pixel defining film PDL3 in one direction is less than the length of the fourth pixel defining film PDL4 in the one direction, the bottom surface of the fourth pixel defining film PDL4 may be exposed without being covered by the third pixel defining film PDL3. In other words, the third pixel defining film PDL3 and the fourth pixel defining film PDL4 may have an eaves-shaped or mushroom-shaped cross-sectional structure.

The light-emitting stack IL may be located on the pixel defining film PDL and the first electrode AND. The light-emitting stack IL may include the first stack layer IL1 and the second stack layer IL2 that emit different lights. When the light-emitting stack IL has a two-tandem structure, one of the first stack layer IL1 and the second stack layer IL2 may emit light that includes the wavelength range of any one of the first light, the second light, and the third light, and the other may emit light that includes the wavelength ranges of the other two lights. For example, the first stack layer IL1 may emit light that includes the wavelength range of the first light and the wavelength range of the third light, and the second stack layer IL2 may emit light that includes the wavelength range of the second light. Here, the first light may be light of a blue wavelength band, the second light may be light of a green wavelength band, and the third light may be light of a red wavelength band.

A charge generation layer for supplying charges or electron valance holes to the second stack layer IL2 and supplying electrons to the first stack layer IL1 may be located between the first stack layer IL1 and the second stack layer IL2. The charge generation layer may include an n-type charge generation layer that supplies electrons to the first stack layer IL1 and a p-type charge generation layer that supplies holes to the second stack layer IL2. The n-type charge generation layer may include a dopant of a metal material.

The first stack layer IL1 need not be formed on the bottom surface of the fourth pixel defining film PDL4 that is exposed without being covered by the third pixel defining film PDL3, and thus may be cut off by the eaves-shaped or mushroom-shaped cross-sectional structure of the third pixel defining film PDL3 and the fourth pixel defining film PDL4. In this case, the first hole transport layer of the first stack layer IL1, and a charge generation layer located between the first stack layer IL1 and the second stack layer IL2 may also be cut off. Further, although FIG. 8 illustrates that the second stack layer IL2 is connected without being cut off, the second hole transport layer of the second stack layer IL2 may be cut off, and the second electron transport layer of the second stack layer IL2 may be connected without being cut off. Therefore, it is possible to prevent a leakage current from flowing through the first hole transport layer of the first stack layer IL1, the second hole transport layer of the second stack layer IL2, and the charge generation layer between the adjacent emission areas EA1, EA2, and EA3. Accordingly, it is possible to prevent the light-emitting stack IL in the adjacent emission areas EA1, EA2, and EA3 from emitting light other than the originally intended light such as due to the influence of the above current.

Although FIG. 8 illustrates a two-tandem structure in which the light-emitting stack IL includes two stack layers IL1 and IL2, the present disclosure is not necessarily limited thereto. For example, the light-emitting stack IL may have a three-tandem structure including three stack layers as shown in FIG. 7. In this case, it may be designed such that the charge generation layer between the first stack layer IL1 and the second stack layer IL2, and the charge generation layer between the second stack layer IL2 and the third stack layer IL3 are cut off by adjusting the height of the third pixel defining film PDL3. Alternatively, as shown in FIG. 7, the trench TRC penetrating the first pixel defining film PDL1, the planarization film PNS, the second pixel defining film PDL2, and the third pixel defining film PDL3 may be added. In this case, the trench TRC may penetrate at least a part of the ninth insulating film INS9, but the present disclosure is not necessarily limited thereto.

Although the embodiment of FIG. 8 is illustrated as not including the optical layer OPL of FIG. 7, the present disclosure is not necessarily limited thereto. The embodiment of FIG. 8 may also further include the optical layer OPL between the adhesive layer ADL and the cover layer CVL.

FIG. 9 shows a display element layer, lenses, and an optical module of a display device according to an embodiment, indicated generally by the reference indicator 10b.

Referring to FIG. 9 in addition to FIGS. 2 and 7, some of the plurality of lenses LNS may be located in a straight line with each of the emission areas EA1, EA2, and EA3, and some others of the plurality of lenses LNS may be located to be shifted in one direction with respect to each of the emission areas EA1, EA2, and EA3.

For example, the display device 10b may include a middle pixel MPX and an edge pixel EPX. The middle pixel MPX refers to the pixel PX positioned in the middle among the pixels PX, and the edge pixel EPX refers to the pixel PX positioned at the edge among the pixels PX.

The plurality of sub-pixels SP1, SP2, and SP3 included in the middle pixel MPX may be located in parallel with the plurality of lenses LNS located above the sub-pixels SP1, SP2, and SP3, respectively. For example, the plurality of sub-pixels SP1, SP2, and SP3 included in the middle pixel MPX may be respectively located in a straight line in the thickness direction (e.g., the third direction DR3) of the display panel 100 with respect to the plurality of lenses LNS located above the sub-pixels SP1, SP2, and SP3.

The plurality of sub-pixels SP1, SP2, and SP3 included in the edge pixel EPX may be respectively located to be shifted by a first distance D1 with respect to the plurality of lenses LNS located above the sub-pixels SP1, SP2, and SP3. For example, the plurality of sub-pixels SP1, SP2, and SP3 included in the edge pixel EPX may be respectively located to be offset horizontally in the thickness direction (e.g., the third direction DR3) of the display panel 100 with respect to the plurality of lenses LNS located above the sub-pixels SP1, SP2, and SP3. For example, pixels located between the middle pixel MPX and the end pixel EPX may be progressively shifted by distances between zero and the first distance D1, and such progressive shifting may occur in two dimensions relative to end pixels on all sides of the display panel.

In the display device 10b according to the present embodiment, the size of the first distance D1 that is the degree to which the plurality of sub-pixels SP1, SP2, and SP3 are shifted with respect to the plurality of lenses LNS may increase in the direction from the middle pixel MPX to the edge pixel EPX. Accordingly, the average luminance amount of the display device 10b according to the present embodiment may be optimized based on the chief ray array (CRA) angle distribution. For example, the overall luminous efficiency of the display device 10b may be optimized from various angles.

Specifically, when light emitted from the plurality of sub-pixels SP1, SP2, and SP3 included in the middle pixel MPX is incident on the optical module 800, the light may be incident generally parallel to a normal line (e.g., the vertical line in the drawing). On the other hand, when light emitted from the plurality of sub-pixels SP1, SP2, and SP3 included in the edge pixel EPX is incident on the optical module 800, the light may be incident generally at a selected angle with respect to the normal line. Accordingly, the shift may be performed by the first distance D1 such that the lens LNS (e.g., approximately the middle of the lens LNS) is located on an extension line extending from the display element layer EML of each of the pixels PX to the incident point of the optical module 800, and the average luminance amount based on the chief ray array (CRA) angle distribution may be optimized.

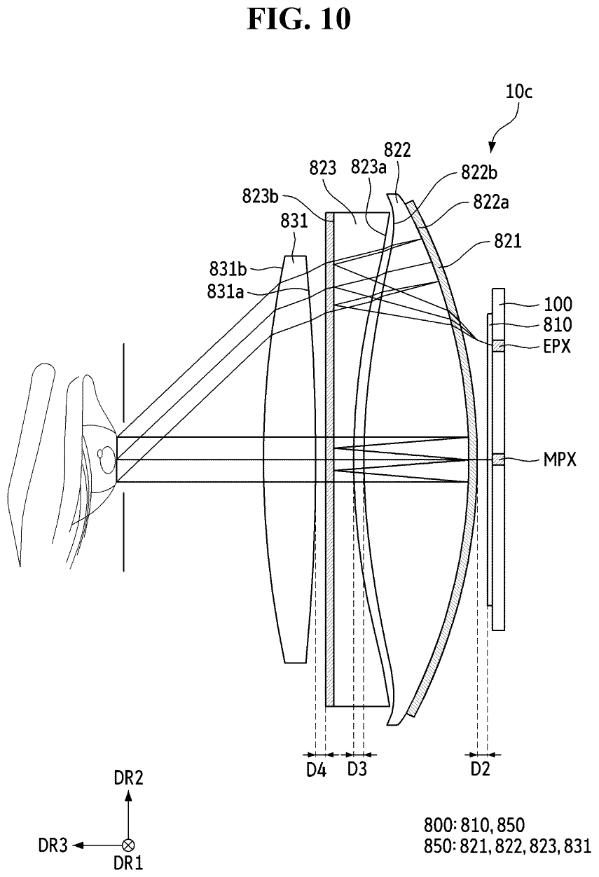

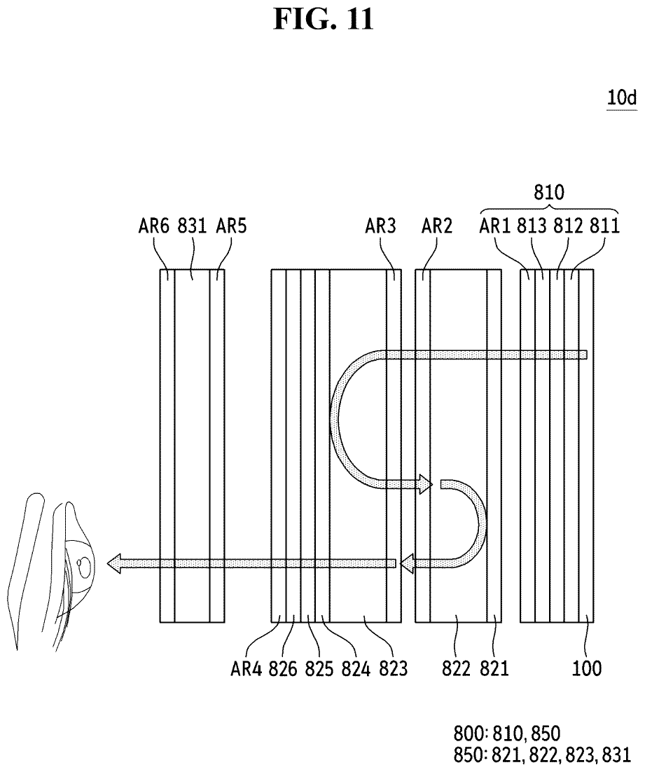

FIG. 10 shows a display device according to an embodiment, indicated generally by the reference indicator 10c. FIG. 11 shows a display device according to an example of the display device 10c of FIG. 10, indicated generally by the reference indicator 10d.

Referring to FIGS. 10 and 11 in addition to FIGS. 7 and 9, the display device 10c or 10d may include the display panel 100 and the optical module 800 located on the display panel 100.

Since the display panel 100 has been described with reference to FIG. 7 or the like, substantially duplicate description of the display panel 100 may be omitted.

The optical module 800 (see FIG. 10 legend) may include a first optical module 810 and an optical array module 850. The first optical module 810 may be located on the display panel 100, and the optical array module 850 may be located on the first optical module 810.

In an embodiment, the first optical module 810 may be located directly on the display panel 100. For example, the first optical module 810 may be directly attached to the display panel 100.

The optical array module 850 may be spaced apart from the first optical module 810 by a second distance D2. An air gap filled with air may be positioned between the optical array module 850 and the first optical module 810.

The first optical module 810 may include a first phase retardation film 811, a first polarizing film 812, a second phase retardation film 813, and a first coating film AR1. The optical array module 850 (see FIG. 10 legend) may include a reflection control film 821, a first lens 822, a second coating film AR2, a third coating film AR3, a second lens 823, a third phase retardation film 824, a second polarizing film 825, a third polarizing film 826, a fourth coating film AR4, a fifth coating film AR5, a third lens 831, and a sixth coating film AR6.

The first optical module 810 may be substantially the same component as the polarizing plate POL of the display panel 100 described with reference to FIG. 7. The display device 10d may include either the polarizing plate POL of the display panel 100 or the first optical module 810 of the optical module 800.

The first phase retardation film 811 may be located on the display panel 100. For example, the first phase retardation film 811 may be located on the cover layer CVL of the display panel 100. The first phase retardation film 811 may delay the phase of light that has passed through the first phase retardation film 811. When linearly polarized light passes through the first phase retardation film 811, the light may be circularly polarized or elliptically polarized, and when circularly polarized or elliptically polarized light passes through the first phase retardation film 811, the light may be linearly polarized. In an embodiment, the first phase retardation film 811 may be a λ/4 plate (quarter-wave plate). In an embodiment, the first phase retardation film 811 may be omitted.

The first polarizing film 812 may be located on the first phase retardation film 811. The first polarizing film 812 may have a first polarization axis extending in one direction. The first polarizing film 812 may be a linear polarizing film. The first polarizing film 812 may linearly polarize light in the direction of the first polarization axis. For example, the first polarizing film 812 may pass light vibrating in a direction parallel to the first polarization axis and may block light vibrating in a direction not parallel to the first polarization axis.

In an embodiment, the first polarizing film 812 may be an absorption-type polarizing film. In this case, the first polarizing film 812 may pass light vibrating in a direction parallel to the first polarization axis and may absorb light vibrating in a direction not parallel to the first polarization axis.

The second phase retardation film 813 may be located on the first polarizing film 812. The second phase retardation film 813 may delay the phase of light that has passed through the second phase retardation film 813. When linearly polarized light passes through the second phase retardation film 813, the light may be circularly polarized or elliptically polarized, and when circularly polarized or elliptically polarized light passes through the second phase retardation film 813, the light may be linearly polarized. In an embodiment, the second phase retardation film 813 may be a λ/4 plate (quarter-wave plate).

The first coating film AR1 may be located on the second phase retardation film 813. The first coating film AR1 may be an anti-reflection film. The first coating film AR1 may be formed by anti-reflection coating. The first coating film AR1 may prevent light passing through the top surface (left side in the drawing) of the first optical module 810 from being reflected. Accordingly, the light output efficiency may be optimized, and the occurrence of stray light may be minimized.

The optical array module 850 may include at least one or more lenses. For example, the optical array module 850 may include the first lens 822, the second lens 823, and the third lens 831. In an embodiment, the first lens 822, the second lens 823, and the third lens 831 may be located to be spaced apart from each other. For example, as illustrated in FIG. 10, the first lens 822 and the second lens 823 may be spaced apart by a third distance D3, and the second lens 823 and the third lens 831 may be spaced apart by a fourth distance D4. The third distance D3 may be a distance between the center portion of the first lens 822 and the center portion of the second lens 823, and the fourth distance D4 may be a distance between the center portion of the second lens 823 and the center portion of the third lens 831.

The first lens 822 may be located on the first optical module 810 and/or on a reflection control film 821. For example, the first lens 822 may be located on the first coating film AR1 of the first optical module 810. The first lens 822 may be spaced apart from the first optical module 810. The first lens 822 may magnify an image formed by light generated from the display panel 100.

The first lens 822 may be a single lens. The first lens 822 be a magnifying lens. In an embodiment, the first lens 822 may include at least one of a convex lens, a meniscus lens, and a Fresnel lens.

In an embodiment, the average curvatures of a first surface 822a and a second surface 822b of the first lens 822 may be different. For example, the average curvature of the first surface 822a of the first lens 822 may be greater than the average curvature of the second surface 822b. In an embodiment, the first surface 822a and the second surface 822b of the first lens 822 may each be aspherical surfaces including a plurality of curvatures. The first surface 822a of the first lens 822 is a surface facing the first optical module 810, and the second surface 822b is a surface located on the opposite side.

In the display device 10d according to the present embodiment, the first lens 822 may include an aspherical surface, and the color crosstalk (or color X-talk) phenomenon may be optimized. In addition, as described above with reference to FIG. 9, by adjusting the first distance D1 that is the degree to which the plurality of sub-pixels SP1, SP2, and SP3 are shifted with respect to the plurality of lenses LNS in the direction from the middle pixel MPX to the edge pixel EPX and simultaneously adjusting each of the plurality of curvatures of the aspherical surface of the first lens 822, the average luminance amount based on the chief ray array (CRA) angle distribution may be further optimized.

The reflection control film 821 may be located on the first optical module 810 and/or on the first lens 822. For example, the reflection control film 821 may be located on the first surface 822a of the first lens 822. The reflection control film 821 may be located between the first lens 822 and the first optical module 810. The reflection control film 821 may transmit part of light and reflect the remaining part. For example, the reflection control film 821 may include a half mirror.

Light transmitted through the reflection control film 821 may be transmitted substantially without phase change. Light reflected from the reflection control film 821 may be reflected with its phase reversed. For example, left-circularly polarized light may be reflected from the reflection control film 821 to be right-circularly polarized light, and the right-circularly polarized light may be reflected from the reflection control film 821 to be left-circularly polarized light.

The reflection control film 821 may be conformally formed based on the shape of the first surface 822a of the first lens 822. Since the first surface 822a of the first lens 822 is an aspherical surface including a plurality of curvatures, the viewing angle and the magnification ratio may be maximized. Accordingly, the number of components of the optical module 800 may be minimized and the thickness of the display device 10d may be minimized.

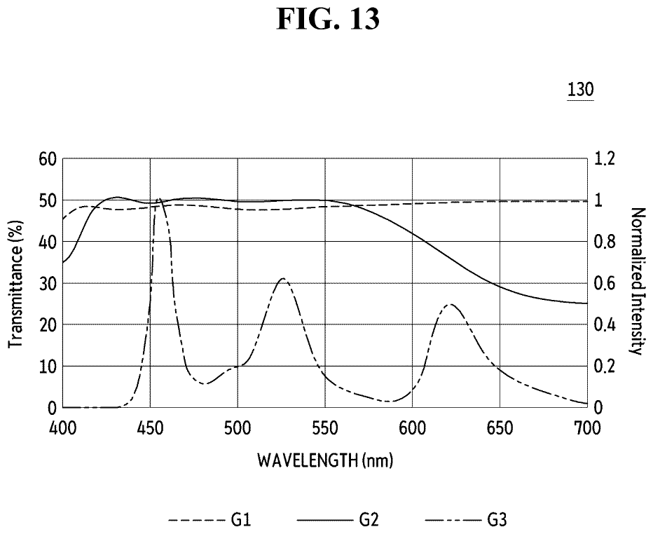

In the display device 10d according to the present embodiment, the transmittance and the reflectivity of the reflection control film 821 may be adjusted to adjust the color temperature characteristics and light efficiency of the display device 10d. For example, a function of the transmittance and the reflectivity of the reflection control film in respect to the light of the blue range may be smaller than the function of the transmittance and the reflectivity of the reflection control film in respect to the light of the green and red wavelength ranges. This may be described in greater detail infra with reference to FIG. 13.

The second coating film AR2 may be located on the first lens 822. For example, the second coating film AR2 may be located on the second surface 822b of the first lens 822. The second coating film AR2 may be an anti-reflection film. The second coating film AR2 may be formed by anti-reflection coating. The second coating film AR2 may prevent light passing through the second surface 822b of the first lens 822 from being reflected. Accordingly, the light output efficiency may be optimized, and the occurrence of stray light may be minimized.

The second lens 823 may be located on the first lens 822. For example, the second lens 823 may be located on the second coating film AR2 of the first lens 822. The second lens 823 may be spaced apart from the first lens 822. The second lens 823 may magnify an image formed by light generated from the display panel 100.

The second lens 823 may be a single lens. The second lens 823 may be a magnifying lens. In an embodiment, the second lens 823 may include at least one of a convex lens, a meniscus lens, and a Fresnel lens.

In an embodiment, the average curvatures of a first surface 823a and a second surface 823b of the second lens 823 may be different. For example, the average curvature of the first surface 823a of the second lens 823 may be greater than the average curvature of the second surface 823b of the second lens 823. In an embodiment, the first surface 823a of the second lens 823 may be an aspherical surface including a plurality of curvatures, and the second surface 823b may be a flat surface. The first surface 823a of the second lens 823 may be a surface facing the first lens 822, and the second surface 823b may be a surface located on the opposite side of the first surface 823a.

In the display device 10d according to the present embodiment, the second lens 823 may include an aspherical surface, and the color crosstalk (or color X-talk) phenomenon may be optimized. In addition, as described above with reference to FIG. 9, by adjusting the first distance D1 that is the degree to which the plurality of sub-pixels SP1, SP2, and SP3 are shifted with respect to the plurality of lenses LNS in the direction from the middle pixel MPX to the edge pixel EPX and simultaneously adjusting each of the plurality of curvatures of the aspherical surface of the second lens 823, the average luminance amount based on the chief ray array (CRA) angle distribution may be further optimized.

The third coating film AR3 may be located on the second lens 823. For example, the third coating film AR3 may be located on the first surface 823a of the second lens 823. The third coating film AR3 may be an anti-reflection film. The third coating film AR3 may be formed by anti-reflection coating. The third coating film AR3 may prevent light passing through the first surface 823a of the second lens 823 from being reflected. Accordingly, the light output efficiency may be optimized, and the occurrence of stray light may be minimized.

The third phase retardation film 824 may be located on the second lens 823. For example, the third phase retardation film 824 may be located on the second surface 823b of the second lens 823. The third phase retardation film 824 may delay the phase of light that has passed through the third phase retardation film 824. When linearly polarized light passes through the third phase retardation film 824, the light may be circularly polarized or elliptically polarized, and when circularly polarized or elliptically polarized light passes through the third phase retardation film 824, the light may be linearly polarized. In an embodiment, the third phase retardation film 824 may be a λ/4 plate (quarter-wave plate).

The second polarizing film 825 may be located on the third phase retardation film 824. The second polarizing film 825 may have a second polarization axis extending in one direction. The second polarizing film 825 may be a linear polarizing film. The second polarizing film 825 may linearly polarize light in the direction of the second polarization axis. For example, the second polarizing film 825 may pass light vibrating in a direction parallel to the second polarization axis and may block light vibrating in a direction not parallel to the second polarization axis.

In an embodiment, the second polarizing film 825 may be a reflective polarizing film. In this case, the second polarizing film 825 may pass light vibrating in a direction parallel to the second polarization axis and may reflect light vibrating in a direction not parallel to the second polarization axis.

The third polarizing film 826 may be located on the second polarizing film 825. The third polarizing film 826 may have a third polarization axis extending in one direction. The third polarizing film 826 may be a linear polarizing film. The third polarizing film 826 may linearly polarize light in the direction of the third polarization axis. For example, the third polarizing film 826 may pass light vibrating in a direction parallel to the third polarization axis and may block light vibrating in a direction not parallel to the third polarization axis. In an embodiment, the third polarizing film 826 may be omitted.

In an embodiment, the third polarizing film 826 may be an absorption-type polarizing film. In this case, the third polarizing film 826 may pass light vibrating in a direction parallel to the third polarization axis and may absorb light vibrating in a direction not parallel to the third polarization axis.

The fourth coating film AR4 may be located on the second surface 823b of the second lens 823. For example, the fourth coating film AR4 may be located on the third polarizing film 826. The fourth coating film AR4 may be an anti-reflection film. The fourth coating film AR4 may be formed by anti-reflection coating. The fourth coating film AR4 may prevent light passing through the second surface 823b of the second lens 823 from being reflected. Accordingly, the light output efficiency may be optimized, and the occurrence of stray light may be minimized.

In an embodiment, the third phase retardation film 824, the second polarizing film 825, the third polarizing film 826, and the fourth coating film AR4 may be conformally formed based on the shape of the second surface 823b of the second lens 823.

The third lens 831 may be located on the second lens 823. For example, the third lens 831 may be located on the fourth coating film AR4. The third lens 831 may be spaced apart from the second lens 823. The third lens 831 may magnify an image formed by light generated from the display panel 100.

The third lens 831 may be a single lens. The third lens 831 may be a magnifying lens. In an embodiment, the third lens 831 may include at least one of a convex lens, a meniscus lens, and a Fresnel lens.

In an embodiment, the average curvatures of a first surface 831a and a second surface 831b of the third lens 831 may be different. For example, the average curvature of the first surface 831a of the third lens 831 may be smaller than the average curvature of the second surface 831b. In an embodiment, each of the first surface 831a and the second surface 831b of the third lens 831 may be an aspherical surface including a plurality of curvatures. The first surface 831a of the third lens 831 may be a surface facing the second lens 823, and the second surface 831b may be a surface located on the opposite side of the first surface 831a.

In the display device 10d according to the present embodiment, the third lens 831 may include an aspherical surface, and the color crosstalk (or color X-talk) phenomenon may be optimized. In addition, as described above with reference to FIG. 9, by adjusting the first distance D1 that is the degree to which the plurality of sub-pixels SP1, SP2, and SP3 are shifted with respect to the plurality of lenses LNS in the direction from the middle pixel MPX to the edge pixel EPX and simultaneously adjusting each of the plurality of curvatures of the aspherical surface of the third lens 831, the average luminance amount based on the chief ray array (CRA) angle distribution may be further optimized.

The fifth coating film AR5 may be located on the first surface 831a of the third lens 831. For example, the fifth coating film AR5 may be located on the fourth coating film AR4. The fifth coating film AR5 may be an anti-reflection film. The fifth coating film AR5 may be formed by anti-reflection coating. The fifth coating film AR5 may prevent light passing through the first surface 831a of the third lens 831 from being reflected. Accordingly, the light output efficiency may be optimized, and the occurrence of stray light may be minimized.

The sixth coating film AR6 may be located on the second surface 831b of the third lens 831. The sixth coating film AR6 may be an anti-reflection film. The sixth coating film AR6 may be formed by anti-reflection coating. The sixth coating film AR6 may prevent light passing through the second surface 831b of the third lens 831 from being reflected. Accordingly, the light output efficiency may be optimized, and the occurrence of stray light may be minimized.

In an embodiment, at least one of the first to sixth coating films AR1 to AR6 may be omitted depending on the degree of optimization in transmittance and reflectivity of each member.

The first polarization axis of the first polarizing film 812 and the second polarization axis of the second polarizing film 825 may be perpendicular to each other. For example, when the first polarization axis extends in the third direction DR3 that is a perpendicular direction, the second polarization axis may extend in a horizontal direction perpendicular to the third direction DR3.

The second phase retardation film 813 may have a first optical axis. The first optical axis of the second phase retardation film 813 may be tilted by an angle in the range of greater than about 0 degrees and less than about 90 degrees relative to the first polarization axis of the first polarizing film 812 and/or the second polarization axis of the second polarizing film 825. In an embodiment, the first optical axis may be tilted by an angle of approximately 45 degrees relative to the first polarization axis and/or the second polarization axis, but the present disclosure is not necessarily limited thereto.

The third phase retardation film 824 may have a second optical axis. The second optical axis of the third phase retardation film 824 may be tilted by an angle in the range of greater than about 0 degrees and less than about 90 degrees relative to the first polarization axis of the first polarizing film 812 and/or the second polarization axis of the second polarizing film 825. In an embodiment, the second optical axis may be tilted by an angle of approximately 45 degrees relative to the first polarization axis and/or the second polarization axis, but the present disclosure is not necessarily limited thereto.

The direction in which the first optical axis of the second phase retardation film 813 is tilted with respect to the first polarization axis and/or the second polarization axis may be opposite to the direction in which the second optical axis of the third phase retardation film 824 is tilted with respect to the first polarization axis and/or the second polarization axis. For example, the second phase retardation film 813 may be tilted in about the −45 degree direction with respect to the first polarization axis and/or the second polarization axis, and the third phase retardation film 824 may be tilted in the +45 degree direction with respect to the first polarization axis and/or the second polarization axis. Alternatively, the second phase retardation film 813 may be tilted in about the +45 degree direction with respect to the first polarization axis and/or the second polarization axis, and the third phase retardation film 824 may be tilted in about the −45 degree direction with respect to the first polarization axis and/or the second polarization axis.

The phase retardation direction of light that has passed through the second phase retardation film 813 may be different from the phase retardation direction of light that has passed through the third phase retardation film 824. For example, light that has passed through the second phase retardation film 813 may be delayed by −λ/4, and light that has passed through the third phase retardation film 824 may be delayed by +λ/4.

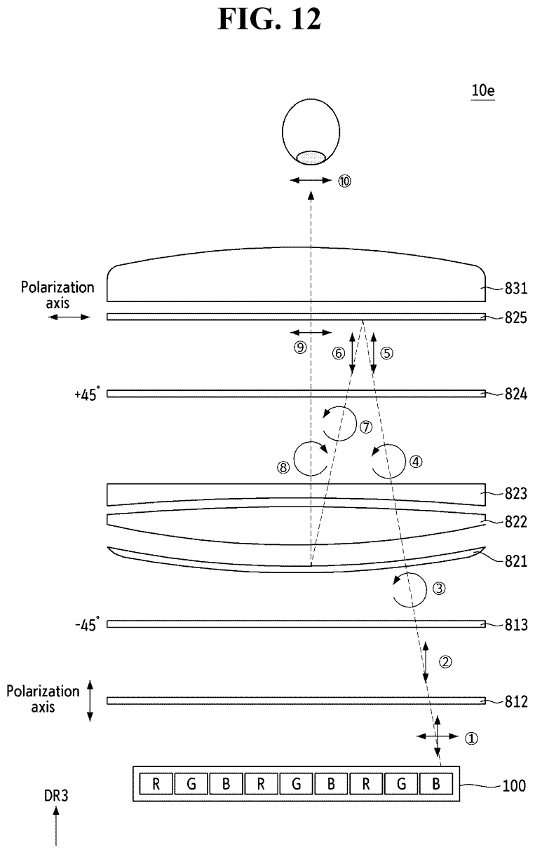

The display device 10d according to the present embodiment may implement folded optics that folds the optical path by including the optical module 800. Accordingly, the total track length, which is the total length of the optical path, may be maximized while simultaneously minimizing the thickness of the display device 10d. This may be described in greater detail infra with reference to FIG. 12.

FIG. 12 shows the path and polarization state of light emitted from a display device according to an embodiment, indicated generally by the reference indicator 10e.

Referring to FIG. 12 in addition to FIGS. 10 and 11, it is illustrated that the first polarization axis of the first polarizing film 812 extends in the perpendicular direction and the second polarization axis of the second polarizing film 825 extends in the horizontal direction. In addition, it is illustrated that the first polarizing film 812 is an absorption-type polarizing film and the second polarizing film 825 is a reflective polarizing film. In addition, it is illustrated that the first optical axis of the second phase retardation film 813 is tilted by about −45 degrees with respect to the perpendicular direction and the second optical axis of the third phase retardation film 824 is tilted by about +45 degrees with respect to the perpendicular direction.

Light emitted from the display panel 100 may be unpolarized light \textcircled{1}.

The unpolarized light \textcircled{1} may pass through the first polarizing film 812 with the first polarization axis in the perpendicular direction and be converted into vertical linear polarized light \textcircled{2} that vibrates in the perpendicular direction.

The vertical linear polarized light \textcircled{2} that has passed through the first polarizing film 812 may pass through the second phase retardation film 813 with the first optical axis tilted by about −45 degrees with respect to the perpendicular direction and be converted into left-circularly polarized light \textcircled{3}.

Part of the left-circularly polarized light \textcircled{3} that has passed through the second phase retardation film 813 may pass through reflection control film 821. The left-circularly polarized light \textcircled{3} that has passed through the reflection control film 821 may have substantially the same polarization state as the left-circularly polarized light \textcircled{3} that has passed through the second phase retardation film 813 without any change in the polarization state. The remaining part of the left-circularly polarized light \textcircled{3} that has passed through the second phase retardation film 813 may be reflected by the reflection control film 821.

The left-circularly polarized light \textcircled{3} that has passed through the reflection control film 821 may pass through the first lens 822 and the second lens 823, and the image may be magnified. Left-circularly polarized light \textcircled{4} that has passed through the first lens 822 and the second lens 823 may have substantially the same polarization state as the left-circularly polarized light \textcircled{3} that has passed through the reflection control film 821 without any change in the polarization state.

The left-circularly polarized light \textcircled{4} that has passed through the first lens 822 and the second lens 823 may pass through the third phase retardation film 824 with the second optical axis tilted by about +45 degrees with respect to the perpendicular direction and be converted back into vertical linear polarized light \textcircled{5}.

Since the vertical linear polarized light \textcircled{5} that has passed through the third phase retardation film 824 is light polarized in a direction different from the second polarization axis in the horizontal direction, the light may be reflected by the second polarizing film 825. Vertical linear polarized light \textcircled{6} reflected from the second polarizing film 825 may have substantially the same polarization state as the vertical linear polarized light \textcircled{5} that has passed through the third phase retardation film 824 without any change in the polarization state.

The vertical linear polarized light \textcircled{6} reflected from the second polarizing film 825 may pass through the third phase retardation film 824 with the second optical axis tilted by about +45 degrees with respect to the perpendicular direction and be converted into left-circularly polarized light \textcircled{7}. When the vertical linear polarized light \textcircled{2} that has passed through the first polarizing film 812 passes through the second phase retardation film 813, the light may pass through the second phase retardation film 813, which has the first optical axis tilted by about −45 degrees with respect to the perpendicular direction, in the third direction DR3 and thus be converted into the left-circularly polarized light \textcircled{3}, and on the other hand, the vertical linear polarized light \textcircled{6} reflected from the second polarizing film 825 may pass through the third phase retardation film 824, which has the second optical axis tilted by about +45 degrees with respect to the perpendicular direction, in a direction opposite to the third direction DR3 and thus be converted into the left-circularly polarized light \textcircled{7}.

The left-circularly polarized light \textcircled{7} that has passed through the third phase retardation film 824 may pass through the first lens 822 and the second lens 823, and the image may be magnified once more. The left-circularly polarized light \textcircled{7} that has passed through the first lens 822 and the second lens 823 may have substantially the same polarization state as the left-circularly polarized light \textcircled{7} that has passed through the third phase retardation film 824 without any change in the polarization state.

Part of the left-circularly polarized light \textcircled{7} that has passed through the first lens 822 and the second lens 823 may be reflected by the reflection control film 821 and be converted into right-circularly polarized light \textcircled{8} by the left and right inversion effect.

The right-circularly polarized light \textcircled{8} reflected from the reflection control film 821 may pass through the first lens 822 and the second lens 823, and the image may be magnified once more. The right-circularly polarized light \textcircled{8} that has passed through the first lens 822 and the second lens 823 may have substantially the same polarization state as the right-circularly polarized light \textcircled{8} reflected from the reflection control film 821 without any change in the polarization state.

The right-circularly polarized light \textcircled{8} that has passed through the first lens 822 and the second lens 823 may pass through the third phase retardation film 824 with the second optical axis tilted by about +45 degrees and be converted into horizontal linear polarized light \textcircled{9}.

Since the horizontal linear polarized light \textcircled{9} that has passed through the third phase retardation film 824 is light polarized in substantially the same direction as the second polarization axis in the horizontal direction, the light may pass through the second polarizing film 825. The horizontal linear polarized light \textcircled{9} that has passed through the second polarizing film 825 may have substantially the same polarization state as the horizontal linear polarized light \textcircled{9} that has passed through the third phase retardation film 824 without any change in the polarization state.

The horizontal linear polarized light \textcircled{9} that has passed through the second polarizing film 825 may pass through the third lens 831, and the image may be magnified. Horizontal linear polarized light \textcircled{10} that has passed through the third lens 831 may have substantially the same polarization state as the horizontal linear polarized light \textcircled{9} that has passed through the second polarizing film 825 without any change in the polarization state. The horizontal linear polarized light \textcircled{10} that has passed through the third lens 831 may be provided to the user.

Since the display device 10e according to the present embodiment includes folded optics, light passes through three lenses a total of seven times, the frequency at which the image is magnified increases, and the degree to which the image is magnified may increase because the optical path increases. Accordingly, the thickness of the display device 10e may be minimized, but a more magnified image may be acquired.

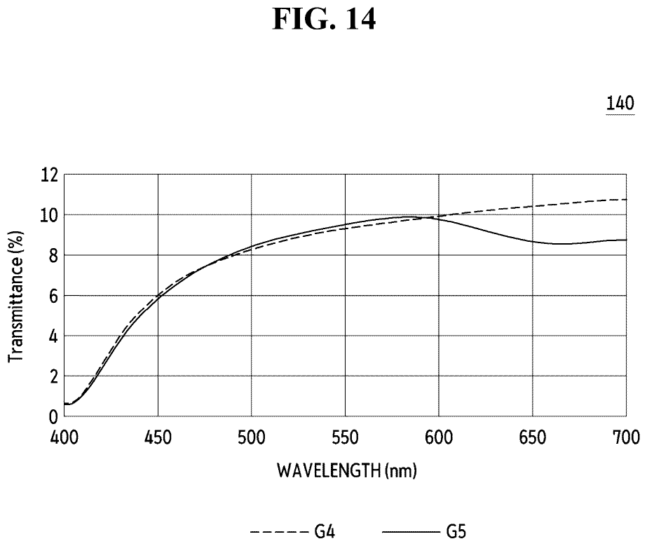

FIG. 13 shows wavelength-specific transmittance of a reflection control film and a graph showing an emission spectrum of a display panel according to a comparative example and an embodiment, indicated generally by the reference indicator 130. FIG. 14 shows wavelength-specific transmittance of a display device according to a comparative example and an embodiment, indicated generally by the reference indicator 140. FIG. 13 shows the transmittance in respect to the reflection control film, and FIG. 14 shows the transmittance in respect to the overall display device.

Referring to FIGS. 13 and 14 in addition to FIGS. 10 to 12, a first graph G1 shows the wavelength-specific transmittance of the reflection control film 821 according to a comparative example. A second graph G2 shows the wavelength-specific transmittance of the reflection control film 821 according to an embodiment. A third graph G3 shows the emission spectrum of the display panel 100 according to the comparative example and an embodiment. A fourth graph G4 shows the wavelength-specific transmittance in respect to the overall display device 10 according to the comparative example, and a fifth graph G5 shows the wavelength-specific transmittance in respect to the overall display device 10e according to an embodiment.

The transmittance of the reflection control film in respect to light of the first wavelength range may be different from the transmittance of the reflection control film in respect to light of the second wavelength range. The reflection control film 821 may transmit part of light and reflect the remaining part. When the amount of light of the same specific wavelength incident upon the reflection control film 821 is substantially 100%, the sum of the transmittance and the reflectivity of the reflection control film 821 in respect to the same specific wavelength may be substantially 100%. For example, when the transmittance of the reflection control film 821 in respect to the same specific wavelength is approximately 50%, the reflectivity may be approximately 50%, and alternatively, when the transmittance of the reflection control film 821 is approximately 25%, the reflectivity may be approximately 75%.

As described above, among the optical path, light emitted from the display panel 100 is transmitted once and reflected once by the reflection control film 821, so from the perspective of the entire display device 10e, the light emission efficiency may be proportional to a function of the transmittance and reflectivity of the reflection control film 821. For example, the function may be a product, a sum, a combination thereof, or the like. Moreover, the function may a multiplicative product of transmittance and reflectivity in respect to light of a same wavelength. Accordingly, in order to maximize the light emission efficiency of the display device 10e, the transmittance and the reflectivity of the reflection control film 821 may each be about 50%.

In the display device 10 according to the comparative example, the transmittance in respect to the light of approximately 400 nm to 700 nm wavelength may be constant at about 50% as shown in the first graph G1 of FIG. 13, and the light emission efficiency of the display device 10e may be maximized.

However, when considering the lifespan and color temperature characteristics of the light-emitting element, the intensity of light in the blue wavelength band, the intensity of light in the green wavelength band, and the intensity of light in the red wavelength band among the light emitted from the display panel 100 may be different from each other. For example, in an embodiment, as shown in the third graph G3 of FIG. 13, the light intensity may be strong in the blue wavelength band, the green wavelength band, and the red wavelength band in the described order.

In an embodiment, the blue wavelength band may indicate that the main peak wavelength of light is contained in a wavelength band of approximately 450 nm to 470 nm, the green wavelength band may indicate that the main peak wavelength of light is contained in a wavelength band of approximately 515 nm to 535 nm, and the red wavelength band may indicate that the main peak wavelength of light is contained in a wavelength band of approximately 620 nm to 640 nm.

The wavelength band of the main peak wavelength is based on the full width at half maximum (FWHM) of the main peak wavelength. For example, the blue wavelength band may have a full width at half maximum of the main peak wavelength of the light of approximately 20 nm to 30 nm, the green wavelength band may have a full width at half maximum of the main peak wavelength of the light of approximately 30 nm to 40 nm, and the red wavelength band may have a full width at half maximum of the main peak wavelength of the light of approximately 30 nm to 40 nm.

In addition, as light emitted from the display panel 100 passes through the optical module 800, the target color temperature characteristics from the perspective of the entire display device 10e may appear different from the color temperature characteristics initially set in the display panel 100. For example, as illustrated in FIG. 14, since light in the blue wavelength band has lower transmittance to the optical module 800 than light in the red wavelength band (or light in a short wavelength band than light in a long wavelength band), a color temperature lower than the originally targeted color temperature may be expressed.

In an embodiment, the display device 10e may prevent such a color temperature reduction phenomenon by making the product of the transmittance and reflectivity of the reflection control film 821 different for each wavelength. For example, the product of the transmittance and reflectivity of the reflection control film 821 for light of a specific wavelength may be different from the product of the transmittance and reflectivity of the reflection control film 821 for light of a different wavelength.

Since the sum of transmittance and reflectivity is substantially constant at about 100%, if either transmittance or reflectivity is adjusted, the product of transmittance and reflectivity may also be determined accordingly. For example, if transmittance and reflectivity are each about 50%, the product of transmittance and reflectivity has a maximum value of about 25%. As another example, even if the transmittance is about 30% and the reflectivity is about 70%, the product of the transmittance and the reflectivity is about 21%, and even if the transmittance is about 70% and the reflectivity is about 30%, the product of the transmittance and the reflectivity is about 21%. Accordingly, the color temperature characteristics of the display device 10e may be adjusted by adjusting the product of the transmittance and reflectivity of the reflection control film 821, adjusting the transmittance, and/or adjusting the reflectivity.

For example, as illustrated in the second graph G2 of FIG. 13, the transmittance of the reflection control film 821 for light in the blue wavelength band and the green wavelength band may be set to approximately 50%, but the transmittance of the reflection control film 821 for light in the red wavelength band may be set to be lower than approximately 50% (for example, approximately 35%). In such case, the product of the transmittance and the reflectance of the reflection control film 821 for light in the blue wavelength band and green wavelength band is approximately 25%, but the product of the transmittance and the reflectivity of the reflection control film 821 for light in the red wavelength band is approximately 23%.

Accordingly, since the light component of the red wavelength band among the light emitted from the display device 10e decreases, the color temperature may increase. For example, from the perspective of the entire display device 10e, the target color temperature characteristic may match the color temperature characteristic set in the initial display panel 100.

TABLE 1

| | | Transmittance | | | |
|---|---|---|---|---|---|
| | | (%) | Wavelength-specific | | |
| | CCT | Total | transmittance (%) | | |
| | (K) | wavelength | 460 nm | 525 nm | 625 nm |
| Comparative | 5597 | 9.3 | 6.6 | 8.9 | 10.2 |
| example | | | | | |
| One embodiment | 6064 | 9.3 | 6.5 | 9.0 | 9.2 |

For example, Table 1 above shows the correlated color temperature (CCT) of the display device 10 according to the comparative example and the display device 10e according to an embodiment, the transmittance of each display device for the total wavelength, and the transmittance of each display device for each wavelength.

As illustrated in the fourth graph G4 of FIG. 14 and Table 1 above, the color temperature of the display device 10 according to the comparative example is approximately 5597 Kelvin (K), the transmittance of the display device 10 for the total wavelength is approximately 9.3%, the transmittance of the display device 10 for a wavelength of 460 nm is approximately 6.6%, the transmittance of the display device 10 for a wavelength of 525 nm is approximately 8.9%, and the transmittance of the display device 10 for a wavelength of 625 nm is approximately 10.2%.

As illustrated in the fifth graph G5 of FIG. 14 and Table 1 above, the color temperature of the display device 10e according to an embodiment is approximately 6064 Kelvin (K), the transmittance of the display device 10e for the total wavelength is approximately 9.3%, the transmittance of the display device 10e for a wavelength of 460 nm is approximately 6.5%, the transmittance of the display device 10e for a wavelength of 525 nm is approximately 9.0%, and the transmittance of the display device 10e for a wavelength of 625 nm is approximately 9.2%.

Compared to the comparative example, it can be seen that the transmittance of the display device 10e according to an embodiment for light of a wavelength of 625 nm of the red wavelength band is reduced by approximately 1%, and accordingly, the correlated color temperature (CCT) is increased by approximately 500 K. On the other hand, it can be seen that the transmittance of the display device 10e for light of the total wavelength is substantially the same at 9.3%, although there is almost no difference in the transmittance for other 460 nm and 525 nm wavelengths and the transmittance for light of the 625 nm wavelength in the red wavelength band decreases by approximately 1%. This is because the degree to which the red wavelength band affects the transmittance of the display device 10e is smaller than that of the green and blue wavelength bands.

In the above, the increase in color temperature by reducing the product of the transmittance and the reflectivity of red wavelength band light has been described as an example, but the present disclosure is not necessarily limited thereto. For example, the target color temperature characteristics of the display device 10e may be freely adjusted by increasing or decreasing the product of the transmittance and the reflectivity of a specific wavelength band light to increase or decrease the color temperature.

The method of making the product of the transmittance and the reflectivity of light of a specific wavelength band different may be performed by controlling the number of stacked layers of the low-refractive-index inorganic insulating film and the high-refractive-index inorganic insulating film of the reflection control film 821 described below and the thickness of each layer.

The reflection control film 821 may include multiple films in which low-refractive-index inorganic insulating films and high-refractive-index inorganic insulating films are alternatively stacked. For example, the low-refractive-index inorganic insulating film may include at least one among silicon oxide (SiOₓ) and silicon oxynitride (SiOₓN_{y}), and the high-refractive-index inorganic insulating film may include at least one among silicon nitride (SiNₓ) and titanium oxide (TiOₓ). In an embodiment, the multiple films of the reflection control film 821 may be formed by a physical vapor deposition such as sputtering, a chemical vapor deposition, or a coating process.

A function of the transmittance and the reflectivity of the reflection control film in respect to light of one wavelength range may be substantially the same as the same function of the transmittance and the reflectivity of the reflection control film in respect to light of the second wavelength range. For example, the first range may be a red light range, the second range may be a green light range, and the function may be the transmittance. Moreover, the function may be a sum of transmittance and reflectivity in respect to light of a same wavelength, band, or range.

TABLE 2

| No. | Material | Thickness(nm) |
|---|---|---|
| 1 | SiO₂ | 87.1 |
| 2 | TiO₂ | 147.5 |
| 3 | SiO₂ | 70.1 |
| 4 | TiO₂ | 54.7 |
| 5 | SiO₂ | 81.1 |
| 6 | TiO₂ | 90.6 |
| 7 | SiO₂ | 221.1 |
| 8 | TiO₂ | 13.6 |
| 9 | SiO₂ | 67.1 |
| 10 | TiO₂ | 23.9 |
| 11 | SiO₂ | 57.2 |
| 12 | TiO₂ | 14.1 |
| 13 | SiO₂ | 215.3 |

Table 2 above shows one example of a stacked structure of the reflection control film 821 having substantially the same transmittance as the second graph G2 of FIG. 13. The first floor is the closest layer to the display panel 100, and the thirteenth floor is the closest layer to the first lens 822. The reflection control film 821 according to the present embodiment is not necessarily limited to the number and thickness of each floor shown in Table 2 above.

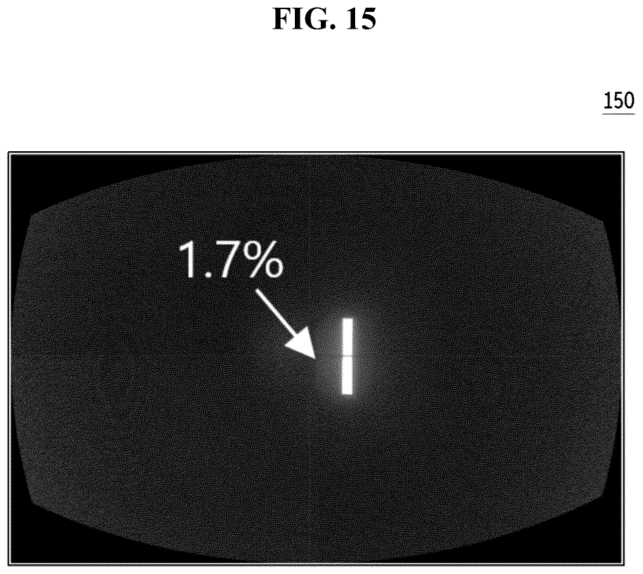

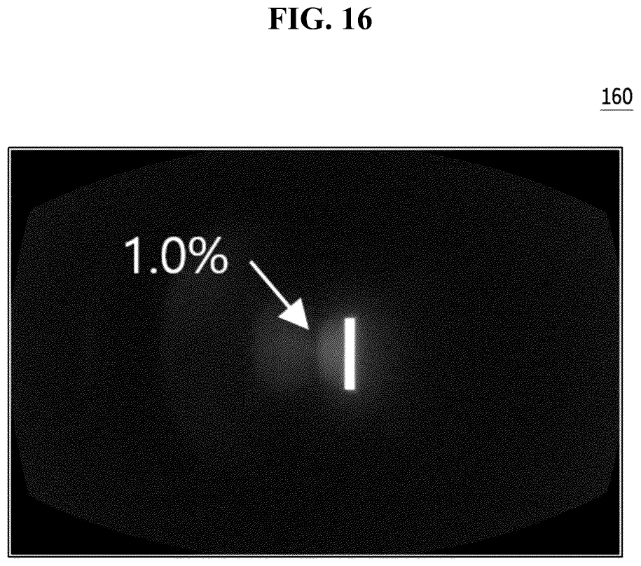

FIG. 15 shows a ghosting phenomenon of a display device according to a comparative example, indicated generally by the reference indicator 150. FIG. 16 shows a ghosting phenomenon of a display device according to an embodiment, indicated generally by the reference indicator 160.

Referring to FIGS. 15 and 16 in addition to FIGS. 10 to 14, FIG. 15 shows ghosting phenomenon of the display device 10 according to the comparative example, and in the display device 10 according to the comparative example, the transmittance of the reflection control film 821 has substantially the same transmittance as the first graph G1 of FIG. 13. FIG. 16 shows ghosting phenomenon of the display device 10e according to an embodiment, and in the display device 10e according to an embodiment, the transmittance of the reflection control film 821 has substantially the same transmittance as the second graph G2 of FIG. 13.

The ghosting phenomenon refers to a phenomenon in which an image other than the original image is seen such as due to reasons such as light emitted from a display panel 100 not traveling along the aforementioned optical path while passing through an optical module 800, light that should not be reflected or transmitted being reflected or transmitted, or diffraction occurring. As illustrated in FIGS. 15 and 16, another image (e.g., light blur) faintly formed on one side of the I-shaped image is an example of a ghosting phenomenon.

In an embodiment, when the product of the transmittance and the reflectance of the reflection control film 821 for light in the red wavelength band is set to be smaller than the product of the transmittance and the reflectance of the reflection control film 821 for light in the green and blue wavelength bands, the ghosting phenomenon may be minimized.

For example, as illustrated in FIG. 15, in the case of the display device 10 according to the comparative example, the luminance of a ghosting image is approximately 1.7%, whereas, as illustrated in FIG. 16, in the case of the display device 10e according to an embodiment, the luminance of a ghosting image is approximately 1.0%.

That is, by setting the product of the transmittance and the reflectivity of the reflection control film 821 for light in the red wavelength band to be smaller than the product of the transmittance and the reflectivity of the reflection control film 821 for light in the green and blue wavelength bands, the ghosting phenomenon may be minimized.

Hereinafter, other embodiments of a display device according to an embodiment may be described. In the following embodiments, the same or like components as those described previously may be referred to by the same or like reference numerals, and overlapping descriptions may be omitted or simplified, focusing mainly on the salient differences.

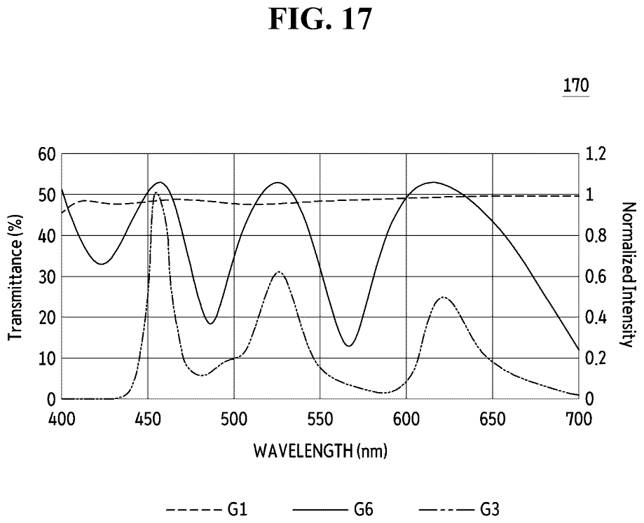

FIG. 17 shows wavelength-specific transmittance of a reflection control film and a graph showing an emission spectrum of a display panel according to a comparative example and an embodiment, indicated generally by the reference indicator 170.

Referring to FIG. 17, the display device 10e′ according to the present embodiment is different from the display device 10e according to the embodiment described with reference to FIG. 13 in that the wavelength-specific transmittance of the reflection control film 821 is different.

More specifically, in the reflection control film 821 of the display device 10e′ of the present embodiment, the transmittance for light having a range overlapping the main peak wavelength of an emission spectrum of the display panel 100 may be higher than the transmittance for light having a range not overlapping the main peak wavelength.

For example, as described above, in the emission spectrum of the display panel 100, the main peak wavelength may be approximately 450 nm to 470 nm for the blue wavelength band, approximately 515 nm to 535 nm for the green wavelength band, and approximately 620 nm to 640 nm for the red wavelength band. The blue wavelength band may have a full width at half maximum of the main peak wavelength of light of a width of approximately 20 nm to 30 nm, the green wavelength band may have a full width at half maximum of the main peak wavelength of light of a width of approximately 30 nm to 40 nm, and the red wavelength band may have a full width at half maximum of the main peak wavelength of light of a width of approximately 30 nm to 40 nm.

As shown in a sixth graph G6 of FIG. 17, the transmittance of the reflection control film 821 may have a high value in the three main peak wavelength bands and a low value in other wavelength bands. Accordingly, the color reproducibility of the display device 10e′ may be optimized. For example, by increasing the transmittance for light in the main peak wavelength band and decreasing the transmittance for other wavelength bands, color purity may be optimized, colors close to the primary colors of red, green, and blue may be implemented, and interference by light of unnecessary wavelengths may be minimized, thereby optimizing the color reproducibility of the display device 10e′.

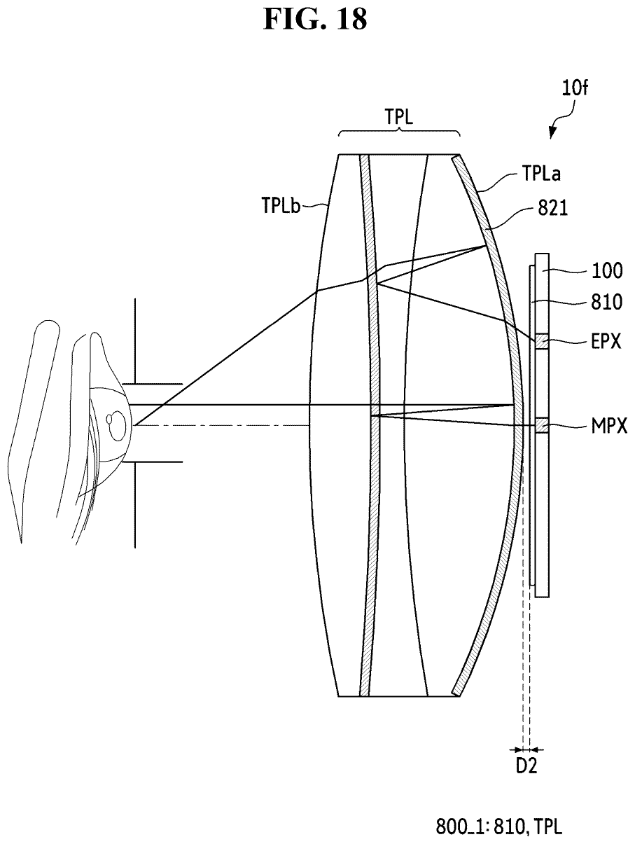

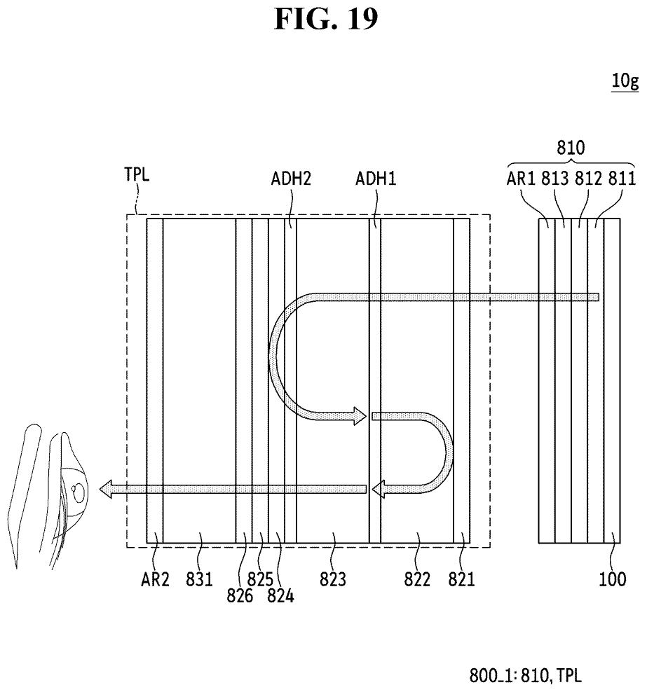

FIG. 18 shows a display device according to an embodiment, indicated generally by the reference indicator 10f. FIG. 19 shows a display device according to an example of the embodiment of FIG. 18, indicated generally by the reference indicator 10g.

Referring to FIGS. 18 and 19, the display device 10g according to the present embodiment is different from the display device 10c according to the embodiment described above with reference to FIG. 10 or the like in that an optical array module TPL is a triplet lens.

More specifically, an optical module 800_1 (see FIG. 18 legend) may include a first optical module 810—and the optical array module TPL. The first optical module 810 may be located on the display panel 100, and the optical array module TPL may be located on the first optical module 810.

The optical array module TPL may include a reflection control film 821, a first lens 822, a first adhesive layer ADH1, a second lens 823, a second adhesive layer ADH2, a third phase retardation film 824, a second polarizing film 825, a third polarizing film 826, a third lens 831, and a second coating film AR2.

The optical array module TPL may be a triplet lens. For example, the optical array module TPL may be a lens in which the first lens 822, the second lens 823, and the third lens 831 are combined, such as by integral manufacture, one or more adhesive layers, captive structural arrangement, or the like. The first adhesive layer ADH1 may be arranged between the first lens 822 and the second lens 823, and the second adhesive layer ADH2 may be arranged between the second lens 823 and the third lens 831. The first lens 822, the second lens 823, and the third lens 831 may be combined with each other by the first adhesive layer ADH1 and the second adhesive layer ADH2.

The display device 10g according to the present embodiment may reduce the thickness of the optical module 800_1 by including a triplet lens. Accordingly, it may become easier to ensure the optimal distance for eye relief. Additionally, the field of view (FOV) may be maximized through aberration correction and focus correction by using a triplet lens. Further, since the triplet lens is included, an air gap located between separate lenses spaced apart from each other may be eliminated, and light loss such as due to reflection at the interface between the air gap and the lens may be minimized, thereby increasing light efficiency.

In an embodiment, the average curvatures of a first surface TPLa and a second surface TPLb of the optical array module TPL may be different. For example, the average curvature of the first surface TPLa of the optical array module TPL may be greater than the average curvature of the second surface TPLb. In an embodiment, the first surface TPLa and the second surface TPLb of the optical array module TPL may be aspherical surfaces including plurality of curvatures. The first surface TPLa of the optical array module TPL is a surface facing the first optical module 810, and the second surface TPLb is a surface located on the opposite side of the first surface TPLa.

In the display device 10g according to the present embodiment, the optical array module TPL may include an aspherical surface, and the color crosstalk (or color X-talk) phenomenon may be optimized. In addition, as described above with reference to FIG. 9, by adjusting the first distance D1 that is the degree to which the plurality of sub-pixels SP1, SP2, and SP3 are shifted with respect to the plurality of lenses LNS in the direction from the middle pixel MPX to the edge pixel EPX and simultaneously adjusting each of the plurality of curvatures of the aspherical surface of the optical array module TPL, the average luminance amount based on the chief ray array (CRA) angle distribution may be further optimized.

The reflection control film 821 may be located on the first surface TPLa of the optical array module TPL. For example, the reflection control film 821 may be located on the first lens 822. The reflection control film 821 may be located between the first lens 822 and the first optical module 810. The reflection control film 821 may transmit part of light and reflect the remaining part. For example, the reflection control film 821 may include a half mirror.

Light transmitted through the reflection control film 821 may be transmitted without phase change. Light reflected from the reflection control film 821 may be reflected with its phase reversed. For example, left-circularly polarized light may be reflected from the reflection control film 821 to be right-circularly polarized light, and the right-circularly polarized light may be reflected from the reflection control film 821 to be left-circularly polarized light.

The reflection control film 821 may be conformally formed based on the shape of the first surface TPLa of the optical array module TPL. Since the first surface TPLa of the optical array module TPL is an aspherical surface including a plurality of curvatures, the viewing angle and the magnification ratio may be maximized. Accordingly, the number of components of the optical module 800_1 may be minimized and the thickness of the display device 10g may be minimized.

The third phase retardation film 824 may be located on the second lens 823. For example, the third phase retardation film 824 may be bonded to the second lens 823 via the second adhesive layer ADH2. The third phase retardation film 824 may delay the phase of light that has passed through the third phase retardation film 824. When linearly polarized light passes through the third phase retardation film 824, the light may be circularly polarized or elliptically polarized, and when circularly polarized or elliptically polarized light passes through the third phase retardation film 824, the light may be linearly polarized. In an embodiment, the third phase retardation film 824 may be a λ/4 plate (quarter-wave plate).

The second polarizing film 825 may be located on the third phase retardation film 824. The second polarizing film 825 may have a second polarization axis extending in one direction. The second polarizing film 825 may be a linear polarizing film. The second polarizing film 825 may linearly polarize light in the direction of the second polarization axis. For example, the second polarizing film 825 may pass light vibrating in a direction parallel to the second polarization axis and may block light vibrating in a direction not parallel to the second polarization axis.

In an embodiment, the second polarizing film 825 may be a reflective polarizing film. In this case, the second polarizing film 825 may pass light vibrating in a direction parallel to the second polarization axis and may reflect light vibrating in a direction not parallel to the second polarization axis.

The third polarizing film 826 may be located on the second polarizing film 825. The third polarizing film 826 may have a third polarization axis extending in one direction. The third polarizing film 826 may be a linear polarizing film. The third polarizing film 826 may linearly polarize light in the direction of the third polarization axis. For example, the third polarizing film 826 may pass light vibrating in a direction parallel to the third polarization axis and may block light vibrating in a direction not parallel to the third polarization axis. In an embodiment, the third polarizing film 826 may be omitted.

In an embodiment, the third polarizing film 826 may be an absorption-type polarizing film. In this case, the third polarizing film 826 may pass light vibrating in a direction parallel to the third polarization axis and may absorb light vibrating in a direction not parallel to the third polarization axis.

The second coating film AR2 may be located on the second surface TPLb of the optical array module TPL. For example, the second coating film AR2 may be located on the third lens 831. The second coating film AR2 may be an anti-reflection film. The second coating film AR2 may be formed by anti-reflection coating. The second coating film AR2 may prevent light passing through the top surface (left side in the drawing) of a second optical module 820 from being reflected. Accordingly, the light output efficiency may be optimized, and the occurrence of stray light may be minimized.

In an embodiment, at least one of the first coating film AR1 or the second coating film AR2 may be omitted depending on the degree of optimization in transmittance and reflectivity of each member.

The display device 10g according to the present embodiment may implement folded optics that folds the optical path by including the optical module 800_1. Accordingly, the total track length, which is the total length of the optical path, may be maximized while simultaneously minimizing the thickness of the display device 10g.

In the display device 10g according to the present embodiment, similar to the display device 10c according to an embodiment described with reference to FIG. 10 or the like, as the reflection control film 821 has different wavelength-specific transmittances, the color temperature characteristics of the display device 10g may be optimized and a ghosting phenomenon may be minimized.

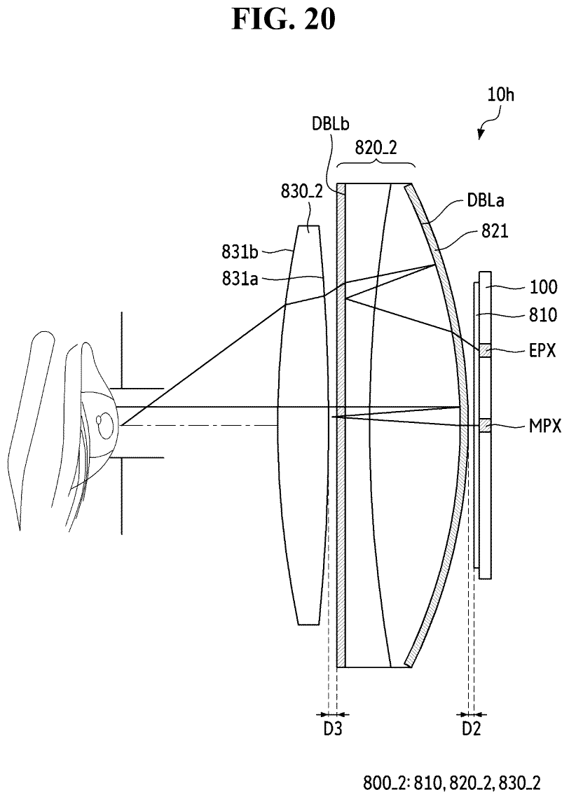

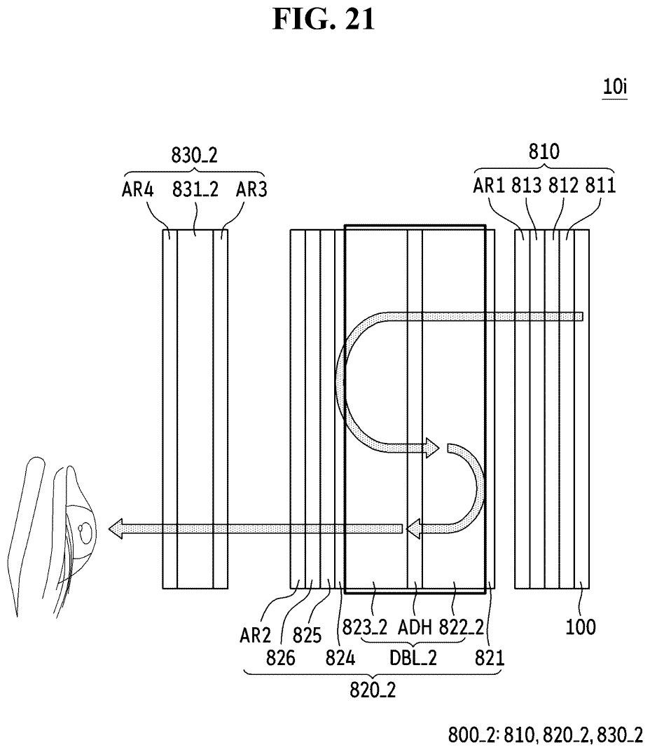

FIG. 20 shows a display device according to an embodiment, indicated generally by the reference indicator 10h. FIG. 21 shows a display device according to an example of the embodiment of FIG. 20, indicated generally by the reference indicator 10i.

Referring to FIGS. 20 and 21, the display device 10i according to the present embodiment is different from the display device 10f according to an embodiment described above with reference to FIG. 18 in that the display device includes a doublet lens instead of a triplet lens.

More specifically, an optical module 800_2 (see FIG. 20 legend) may include a first optical module 810, a second optical module 820_2, and a third optical module 830_2. The first optical module 810 may be located on the display panel 100, the second optical module 820_2 may be located on the first optical module 810, and the third optical module 830_2 may be located on the second optical module 820_2.

In an embodiment, the second optical module 820_2 may be spaced apart from the first optical module 810 by a second distance D2, and the third optical module 830_2 may be spaced apart from the second optical module 820_2 by a third distance D3. A gap, such as an air gap filled with air or other substantially inert gas, may be positioned between the second optical module 820_2 and the first optical module 810 and between the third optical module 830_2 and the second optical module 820_2, respectively.

The second optical module 820_2 may include a reflection control film 821, a first lens DBL_2, a third phase retardation film 824, a second polarizing film 825, a third polarizing film 826, and a second coating film AR2. The third optical module 830_2 may include a second lens 831_2, a third coating film AR3, and a fourth coating film AR4. The first lens DBL_2 of the second optical module 820_2 may include a first sub-lens 822_2 and a second sub-lens 823_2.

The first lens DBL_2 may be located on the first optical module 810. For example, the first lens DBL_2 may be located on the first coating film AR1 of the first optical module 810. The first lens DBL_2 may be spaced apart from the first optical module 810. Moreover, the first lens DBL_2 may magnify an image formed by light generated from the display panel 100.

The first lens DBL_2 may be a doublet lens. For example, the first lens DBL_2 may be a lens in which the first sub-lens 822_2 and the second sub-lens 823_2 are combined. Another adhesive layer ADH may be located between the first sub-lens 822_2 and the second sub-lens 823_2. The first sub-lens 822_2 and the second sub-lens 823_2 may be combined by the adhesive layer ADH.

The display device 10i according to the present embodiment may reduce the thickness of the optical module 800_2 by including a doublet lens. Accordingly, it may become easier to ensure the optimal distance for eye relief. Additionally, the field of view (FOV) may be maximized through aberration correction and focus correction by using a doublet lens. Further, since the doublet lens is included, an air gap located between separate lenses spaced apart from each other may be eliminated, and light loss such as due to reflection at the interface between the air gap and the lens may be minimized, thereby increasing light efficiency.

In an embodiment, the average curvatures of a first surface DBL_2a and a second surface DBL_2b of the first lens DBL_2 may be different. For example, the average curvature of the first surface DBL_2a of the first lens DBL_2 may be greater than the average curvature of the second surface DBL_2b. In an embodiment, the first surface DBL_2a of the first lens DBL_2 may be an aspherical surface including multiple curvatures, and the second surface DBL_2b may be a flat surface, but the present disclosure is not necessarily limited thereto. The first surface DBL_2a of the first lens DBL_2 may be a surface facing the first optical module 810, and the second surface DBL_2b may be a surface facing the third optical module 830_2.

In the display device 10i according to the present embodiment, the first lens DBL_2 may include an aspherical surface, and the color crosstalk (or color X-talk) phenomenon may be optimized. In addition, as described above with reference to FIG. 9, by adjusting the first distance D1 that is the degree to which the plurality of sub-pixels SP1, SP2, and SP3 are shifted with respect to the plurality of lenses LNS in the direction from the middle pixel MPX to the edge pixel EPX and simultaneously adjusting each of the plurality of curvatures of the aspherical surface of the first lens DBL_2, the average luminance amount based on the chief ray array (CRA) angle distribution may be further optimized.

The reflection control film 821 may be located on the first surface DBL_2a of the first lens DBL_2. The reflection control film 821 may be located between the first lens DBL_2 and the first optical module 810. The reflection control film 821 may transmit part of light and reflect the remaining part. For example, the reflection control film 821 may include a half mirror.

Light transmitted through the reflection control film 821 may be transmitted without phase change. Light reflected from the reflection control film 821 may be reflected with its phase reversed. For example, left-circularly polarized light may be reflected from the reflection control film 821 to be right-circularly polarized light, and the right-circularly polarized light may be reflected from the reflection control film 821 to be left-circularly polarized light.

The reflection control film 821 may be conformally formed based on the shape of the first surface DBL_2a of the first lens DBL_2. Since the first surface DBL_2a of the first lens DBL_2 is an aspherical surface including a plurality of curvatures, the viewing angle and the magnification ratio may be maximized. Accordingly, the number of components of the optical module 800_2 may be minimized and the thickness of the display device 10i may be minimized.

The third phase retardation film 824 may be located on the second surface DBL_2b of the first lens DBL_2.

The second coating film AR2 may be located on the third polarizing film 826. The second coating film AR2 may be an anti-reflection film. The second coating film AR2 may be formed by anti-reflection coating. The second coating film AR2 may prevent light passing through the second surface DBL_2b of the first lens DBL_2 from being reflected. Accordingly, the light output efficiency may be optimized, and the occurrence of stray light may be minimized.

The second lens 831_2 may be located on the second optical module 820_2. For example, the second lens 831_2 may be located on the second coating film AR2 of the second optical module 820_2. The second lens 831_2 may be spaced apart from the second optical module 820_2. The second lens 831_2 may magnify an image formed by light generated from the display panel 100.

The second lens 831_2 may be a single lens. The second lens 831_2 may be a magnifying lens. In an embodiment, the second lens 831_2 may include at least one of a convex lens, a meniscus lens, and a Fresnel lens.

In an embodiment, the average curvatures of a first surface 831a and a second surface 831b of the second lens 831_2 may be different. For example, the average curvature of the first surface 831a of the second lens 831_2 may be smaller than the average curvature of the second surface 831b of the second lens 831_2. In an embodiment, the first surface 831a and the second surface 831b of the second lens 831_2 may be aspherical surfaces including a plurality of curvatures. The first surface 831a of the second lens 831_2 may be a surface facing the second optical module 820_2, and the second surface 831b may be a surface located on the opposite side of the first surface 831a.

In the display device 10i according to the present embodiment, the second lens 831_2 may include an aspherical surface, and the color crosstalk (or color X-talk) phenomenon may be optimized. In addition, as described above with reference to FIG. 9, by adjusting the first distance D1 that is the degree to which the plurality of sub-pixels SP1, SP2, and SP3 are shifted with respect to the plurality of lenses LNS in the direction from the middle pixel MPX to the edge pixel EPX and simultaneously adjusting each of the plurality of curvatures of the aspherical surface of the second lens 831_2, the average luminance amount based on the chief ray array (CRA) angle distribution may be further optimized.

The third coating film AR3 and the fourth coating film AR4 may be located on the second lens 831_2. For example, the third coating film AR3 may be located on the first surface 831a of the second lens 831_2, and the fourth coating film AR4 may be located on the second surface 831b of the second lens 831_2. The third coating film AR3 and the fourth coating film AR4 may be anti-reflection films. The third coating film AR3 and the fourth coating film AR4 may be formed by anti-reflection coating. The third coating film AR3 and the fourth coating film AR4 may prevent light passing through the first surface 831a and the second surface 831b of the second lens 831_2 from being reflected. Accordingly, the light output efficiency may be optimized, and the occurrence of stray light may be minimized.

In an embodiment, at least one of the first coating film AR1, the second coating film AR2, the third coating film AR3, and the fourth coating film AR4 may be omitted depending on the degree of optimization in transmittance and reflectivity of each member.

The display device 10i according to the present embodiment may implement folded optics that folds the optical path by including the optical module 800_2. Accordingly, the total track length, which is the total length of the optical path, may be maximized while simultaneously minimizing the thickness of the display device 10i.

In the display device 10i according to the present embodiment, similar to the display device 10c according to an embodiment described with reference to FIG. 10 or the like, as the reflection control film 821 has different wavelength-specific transmittances, the color temperature characteristics of the display device 10i may be optimized and a ghosting phenomenon may be minimized.

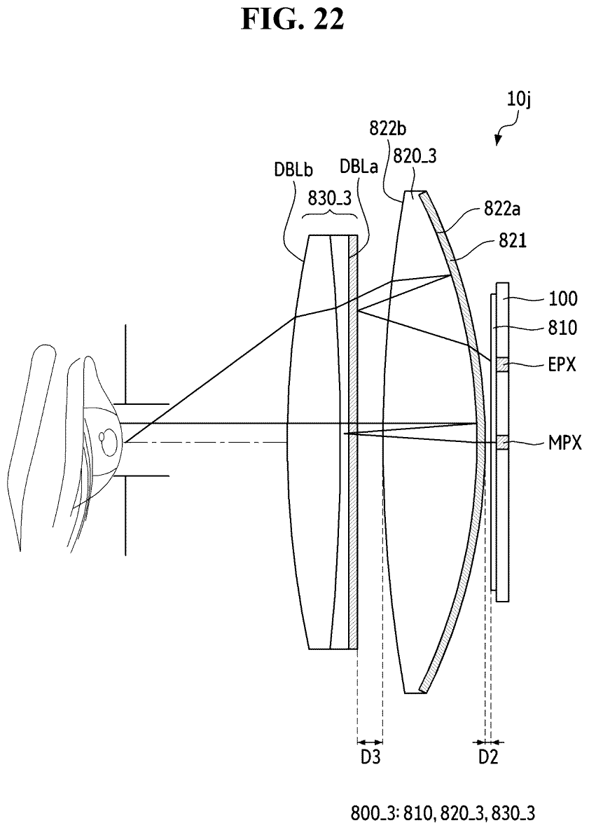

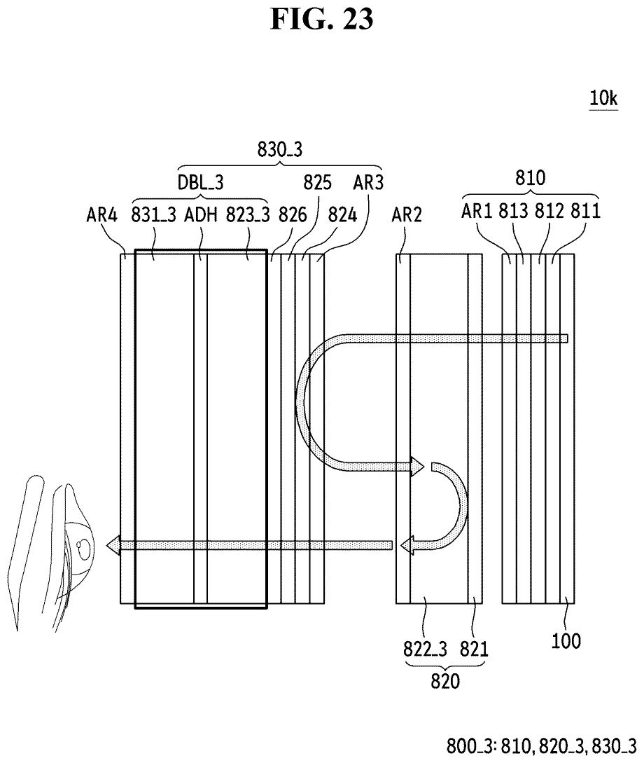

FIG. 22 shows a display device according to an embodiment, indicated generally by the reference indicator 10j. FIG. 23 shows a display device according to an example of the embodiment of FIG. 22, indicated generally by the reference indicator 10k.

Referring to FIGS. 22 and 23, the display device 10k according to the present embodiment is different from the display device 10h according to an embodiment described with reference to FIG. 20 or the like in that a third optical module 830_3 includes a doublet lens.

For example, a second optical module 820_3 may include a reflection control film 821, the first lens 822_3, and a second coating film AR2. The third optical module 830_3 may include a third coating film AR3, a third phase retardation film 824, a second polarizing film 825, a third polarizing film 826, a second lens DBL_3, and a fourth coating film AR4. The second lens DBL_3 of the third optical module 830_3 may include a first sub-lens 831_3 and a second sub-lens 823_3.

Moreover, the first lens 822_3 may be located on the first optical module 810. For example, the first lens 822_3 may be located on the first coating film AR1 of the first optical module 810. The first lens 822_3 may be spaced apart from the first optical module 810. The first lens 822_3 may magnify an image formed by light generated from the display panel 100.

The first lens 822_3 may be a single lens. The first lens 822_3 may be a magnifying lens. In an embodiment, the first lens 822_3 may include at least one of a convex lens, a meniscus lens, and a Fresnel lens.

In an embodiment, the average curvatures of a first surface 822a and a second surface 822b of the first lens 822_3 may be different. For example, the average curvature of the first surface 822a of the first lens 822_3 may be greater than the average curvature of the second surface 822b of the first lens 822_3. In an embodiment, the first surface 822a and the second surface 822b of the first lens 822_3 may be aspherical surfaces including a plurality of curvatures. The first surface 822a of the first lens 822_3 may be a surface facing the first optical module 810, and the second surface 822b may be a surface facing the third optical module 830_3.

In the display device 10k according to the present embodiment, the first lens 822_3 may include an aspherical surface, and the color crosstalk (or color X-talk) phenomenon may be optimized. In addition, as described above with reference to FIG. 9, by adjusting the first distance D1 that may be the degree to which the plurality of sub-pixels SP1, SP2, and SP3 are shifted with respect to the plurality of lenses LNS in the direction from the middle pixel MPX to the edge pixel EPX, and simultaneously adjusting each of the plurality of curvatures of the aspherical surface of the first lens 822_3, the average luminance amount based on the chief ray array (CRA) angle distribution may be further optimized.

The reflection control film 821 may be located on the first surface 822a of the first lens 822_3. The reflection control film 821 may be located between the first lens 822_3 and the first optical module 810. The reflection control film 821 may transmit part of the incident light and reflect the remaining part. For example, the reflection control film 821 may include a half mirror.

Light transmitted through the reflection control film 821 may be transmitted without phase change. Light reflected from the reflection control film 821 may be reflected with its phase reversed. For example, left-circularly polarized light may be reflected from the reflection control film 821 to be right-circularly polarized light, and the right-circularly polarized light may be reflected from the reflection control film 821 to be left-circularly polarized light.

The reflection control film 821 may be conformally formed based on the shape of the first surface 822a of the first lens 822_3. Since the first surface 822a of the first lens 822_3 is an aspherical surface including a plurality of curvatures, the viewing angle and the magnification ratio may be maximized.

An optical module 800_3 (see FIG. 22 legend) may include a first optical module 810, a second optical module 820_3, and a third optical module 830_3. The first optical module 810 may be located on the display panel 100, the second optical module 820_3 may be located on the first optical module 810, and the third optical module 830_3 may be located on the second optical module 820_3. Accordingly, the number of components of an optical module 800_3 may be minimized and the thickness of the display device 10k may be minimized.

The second coating film AR2 may be located on the second surface 822b of the first lens 822_3. The second coating film AR2 may be an anti-reflection film. The second coating film AR2 may be formed by anti-reflection coating. The second coating film AR2 prevent light passing through the second surface 822b of the first lens 822_3 from being reflected. Accordingly, the light output efficiency may be optimized, and the occurrence of stray light may be minimized.

The second lens DBL_3 may be located on the second optical module 822_3. For example, the second lens DBL_3 may be located on the second coating film AR2. The second lens DBL_3 may be spaced apart from the second optical module 822_3. The second lens DBL_3 may magnify an image formed by light generated from the display panel 100.

The second lens DBL_3 may be a doublet lens. For example, the second lens DBL_3 may be a lens in which the first sub-lens 831_3 and the second sub-lens 823_3 are combined. Another adhesive layer ADH may be located between the first sub-lens 831_3 and the second sub-lens 823_3. The first sub-lens 831_3 and the second sub-lens 823_3 may be combined by the adhesive layer ADH.

The display device 10k according to the present embodiment may reduce the thickness of the optical module 800_3 by including a doublet lens. Accordingly, it may become easier to ensure the optimal distance for eye relief. Additionally, the field of view (FOV) may be maximized through aberration correction and focus correction by using a doublet lens. Further, since the doublet lens is included, an air gap located between separate lenses spaced apart from each other may be eliminated, and light loss such as due to reflection at the interface between the air gap and the lens may be minimized, thereby increasing light efficiency.

In an embodiment, the average curvatures of a first surface DBLa and a second surface DBLb of the second lens DBL_3 may be different. For example, the average curvature of the first surface DBLa of the second lens DBL_3 may be smaller than the average curvature of the second surface DBLb. In an embodiment, the first surface DBLa of the second lens DBL_3 may be a flat surface, and the second surface DBLb may be an aspherical surface including a plurality of curvatures, but the present disclosure is not necessarily limited thereto. The first surface DBLa of the second lens DBL_3 may be a surface facing the second optical module 822_3, and the second surface DBLb may be a surface located on the opposite side of the first surface DBLa.

In the display device 10k according to the present embodiment, the second lens DBL_3 may include an aspherical surface, and the color crosstalk (or color X-talk) phenomenon may be optimized. In addition, as described above with reference to FIG. 9, by adjusting the first distance D1 that is the degree to which the plurality of sub-pixels SP1, SP2, and SP3 are shifted with respect to the plurality of lenses LNS in the direction from the middle pixel MPX to the edge pixel EPX and simultaneously adjusting each of the plurality of curvatures of the aspherical surface of the second lens DBL_3, the average luminance amount based on the chief ray array (CRA) angle distribution may be further optimized.

The third phase retardation film 824, the second polarizing film 825, and the third polarizing film 826 may be located on the first surface DBLa of the second lens DBL_3.

The third coating film AR3 may be located on the third phase retardation film 824. The third coating film AR3 may be an anti-reflection film. The third coating film AR3 may be formed by anti-reflection coating. The third coating film AR3 may prevent light passing through the first surface DBLa of the second lens DBL_3 from being reflected. Accordingly, the light output efficiency may be optimized, and the occurrence of stray light may be minimized.

The fourth coating film AR4 may be located on the second surface DBLb of the second lens DBL_3. The fourth coating film AR4 may be an anti-reflection film. The fourth coating film AR4 may be formed by anti-reflection coating. The fourth coating film AR4 may be prevent light passing through the second surface DBLb of the second lens DBL_3 from being reflected. Accordingly, the light output efficiency may be optimized, and the occurrence of stray light may be minimized.

The display device 10k according to the present embodiment may implement folded optics that folds the optical path by including the optical module 800_3. Accordingly, the total track length, which is the total length of the optical path, may be maximized while simultaneously minimizing the thickness of the display device 10k.

In the display device 10k according to the present embodiment, similar to the display device 10c according to an embodiment described with reference to FIG. 10 or the like, as the reflection control film 821 has different wavelength-specific transmittances, the color temperature characteristics of the display device 10k may be optimized and a ghosting phenomenon may be minimized. Moreover, the color temperature characteristics may be based on transmittance and reflectivity for each wavelength range that may be functionally evaluated by one or more functions. In addition, the color temperature values may be adjusted at one or more wavelengths in each respective wavelength range, such as at or about but not necessarily limited to the wavelength peaks or centers of known human vision types such as monochromatic, dichromatic, anomalous trichromatic, normal trichromatic, variant trichromatic, and/or tetrachromatic vision types. In addition, such functions may be adapted to a user's vision type.

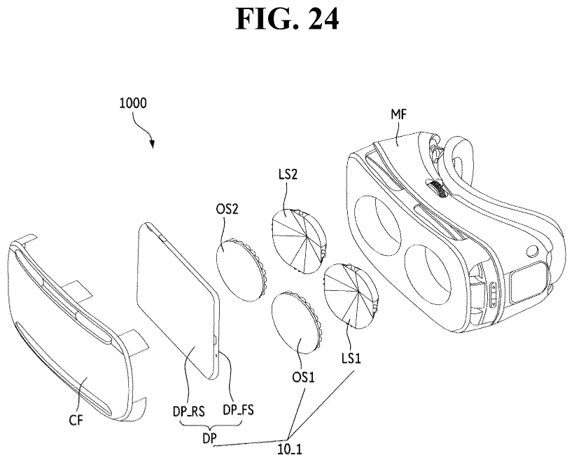

FIG. 24 shows a head-mounted display according to an embodiment, indicated generally by the reference indicator 1000.

Referring to FIG. 24, a head-mounted display 1000 is configured in the form of glasses or a head mount to provide an image to a user using a display device 10_1.

The head-mounted display 1000 may include a see-through type that provides augmented reality based on actual external objects and a see-closed type that provides virtual reality to the user on a screen independent from the external objects.

The head-mounted display 1000 may include a main frame MF mounted on the user's body, the display device 10_1 mounted on the main frame MF to display an image, and a cover frame CF that covers the display device 10_1.

The display device 10_1 may be formed integrally with the head-mounted display 1000 that may be carried by the user and easily attached to or detached from a face or a head, and may be formed to be assembled to the head-mounted display 1000. The display device 10_1 may be substantially the same as the display device 10 described in conjunction with FIG. 1 or the like.

The display device 10_1 may include a display panel DP that displays an image, first and second lens frames OS1 and OS2 that refract an image display light, and first and second multi-channel lenses LS1 and LS2 that form an optical path where the image display light of the display panel DP is visible to the user.

The main frame MF may be worn on the user's face and head. For example, the main frame MF may be formed in a shape corresponding to the user's head and facial structure.

The main frame MF may be integrally formed with display device 10_1. For example, the display panel DP, the first and second lens frames OS1 and OS2, and the first and second multi-channel lenses LS1 and LS2. Alternatively, the display panel DP, the first and second lens frames OS1 and OS2, and the first and second multi-channel lenses LS1 and LS2 may be assembled and mounted to the main frame MF. For example, the main frame MF may have a space or a structure for accommodating the display panel DP, the first and second lens frames OS1 and OS2, and the first and second multi-channel lenses LS1 and LS2. The main frame MF may further include a structure such as a strap or a band to facilitate the mounting, and a controller, an image processing unit, and a lens accommodating unit may be further included in the main frame MF.

The display panel DP may be divided into a front surface DP_FS where an image is displayed, and a rear surface DP_RS positioned on the opposite side of the front surface DP_FS. Image display light may be emitted from the front surface DP_FS of the display panel DP. As may be described in greater detail infra, the first and second lens frames OS1 and OS2 may be located on the front surface DP_FS of the display panel DP, and the first and second multi-channel lenses LS1 and LS2 may be located on the front surfaces of the first and second lens frames OS1 and OS2. At least one infrared camera may be located on at least one of the front surface DP_FS or the rear surface DP_RS of the display panel DP. The display panel DP may be substantially the same as the display panel 100 described in conjunction with FIG. 1 or the like.

The display panel DP may be built in the main frame MF in a state where the first and second lens frames OS1 and OS2 and the first and second multi-channel lenses LS1 and LS2 are mounted and fixed, or may be detachably assembled to the main frame MF. The display panel DP may be opaque, transparent, or translucent depending on the design or usage type of the display device 10_1.

Each of the first and second lens frames OS1 and OS2 may have an area corresponding to the image display surface of the display panel DP, and may be formed in a shape corresponding to that of the image display surface. Further, the first and second lens frames OS1 and OS2 may be formed to have an area and a shape corresponding to those of the rear surfaces of the first and second multi-channel lenses LS1 and LS2, respectively. The rear surfaces of the first and second lens frames OS1 and OS2 may be attached to the image display surface of the display panel DP, and the first and second multi-channel lenses LS1 and LS2 may be attached to the front surfaces of the first and second lens frames OS1 and OS2, respectively. The first and second lens frames OS1 and OS2 may refract the image display light emitted from the image display surface of the display panel DP at a preset angle and provide it to the first and second multi-channel lenses LS1 and LS2 located on the front surfaces thereof, respectively.

In greater detail, the first and second lens frames OS1 and OS2 may refract the image display light, which is emitted from the image display surface of the display panel DP towards the front side, towards an outer side, or towards an outer peripheral side, compared to the front side and provide it to the first and second multi-channel lenses LS1 and LS2 located on the front surfaces thereof, respectively. In particular, the first and second lens frames OS1 and OS2 may refract the image display light incident on the rear surfaces thereof towards the outer side, or towards the outer peripheral side, and provide it to the rear surfaces of the first and second multi-channel lenses LS1 and LS2, respectively.

The first and second multi-channel lenses LS1 and LS2 may form a path for light emitted through the first and second lens frames OS1 and OS2, where the image display light may be visible to the user's eyes on the front side.

The first and second multi-channel lenses LS1 and LS2 may provide a plurality of paths or channels through which the image display light emitted from the display panel DP passes. The plurality of channels may provide the image display light emitted from the display panel DP to the user through different paths. The image display light emitted through the first and second lens frames OS1 and OS2 may be incident on the respective channels, and the image magnified through the respective channels may be focused on the user's eyes.

The first and second multi-channel lenses LS1 and LS2 may be arranged on the front surfaces the first and second lens frames OS1 and OS2 to correspond to the positions of the user's left eye and right eye, respectively. The first and second multi-channel lenses LS1 and LS2 may be accommodated in the main frame MF.

The first and second multi-channel lenses LS1 and LS2 may refract and/or reflect the image display light emitted through the first and second lens frames OS1 and OS2 at least once to form a path to the user's eyes. At least one infrared light source may be located at the main frame MF, or on one side of each of the first and second multi-channel lenses LS1 and LS2 facing the user's eyes.

The cover frame CF may be located on the rear surface DP_RS of the display panel DP to cover the display panel DP, which may protect the display panel DP. The cover frame CF may be attached to the main frame MF while covering the display panel DP.

The display device 10_1 may further include a controller for controlling the overall operation of the display device 10_1 including the display panel DP. The controller may control the image display operation of the display panel DP and audio devices. Specifically, the controller performs image processing (e.g., image mapping) based on the magnification ratio and the image display path corresponding to the first and second lens frames OS1 and OS2 and the first and second multi-channel lenses LS1 and LS2, and controls the mapped image to be displayed on the display panel DP. The controller may be implemented as a dedicated processor including an embedded processor and/or a general-purpose processor including a central processing unit or an application processor, but is not necessarily limited thereto.

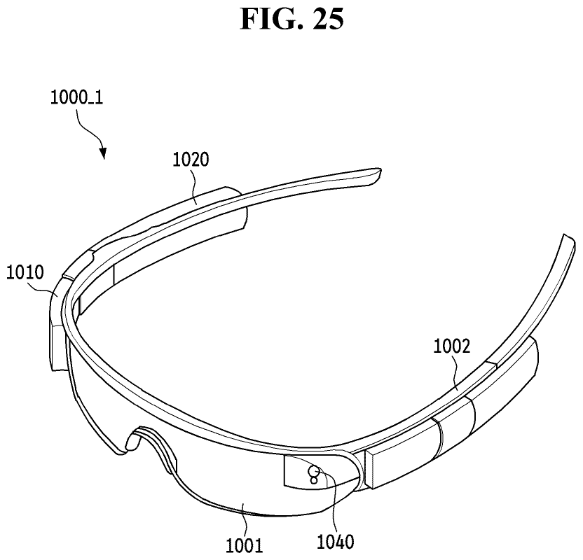

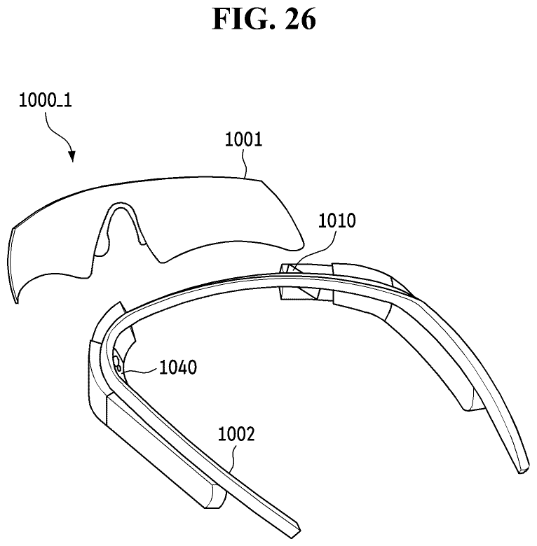

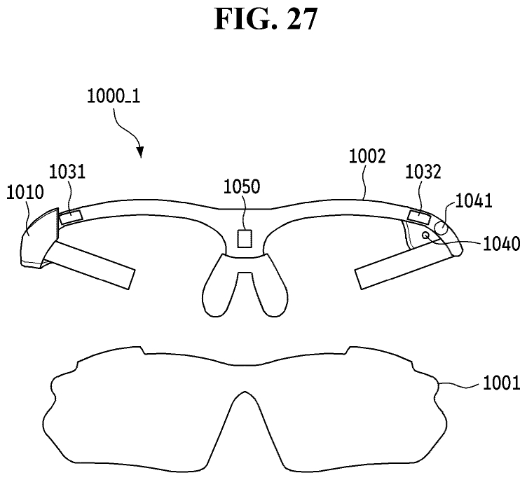

FIG. 25 shows an augmented reality content providing device according to an embodiment, indicated generally by the reference indicator 1000.1. FIG. 26 shows another view of the augmented reality content providing device 1000.1 of FIG. 25. FIG. 27 shows yet another view of the augmented reality content providing device 1000.1 of FIG. 25.

Referring to FIGS. 25 to 27, an augmented reality content providing device 1000_1 may include a support frame 1002 supporting at least one transparent lens 1001, at least one image display module 1010, a surrounding environment detector 1040, and a control module 1020.

The support frame 1002 may be configured in the form of glasses including a spectacle frame supporting the edge of at least one transparent lens 1001 and spectacle frame legs. The shape of the support frame 1002 is not necessarily limited to a glasses type, and may be formed in a goggle type including the transparent lens 1001, or a head-mounted type.

The transparent lens 1001 may include left and right parts formed integrally, or first and second transparent lenses formed separately. The transparent lens 1001, which includes the integrated left and right parts or the separated first and second transparent lenses, may include glass and/or plastic that is transparent or translucent. Accordingly, the user may view the image of reality through the transparent lens 1001 that includes the integrated right and left parts or the separated first and second transparent lenses. Here, the transparent lens 1001 being the integrated lens or the first and second transparent lenses, may have a refractive power in consideration of the user's eyesight.

The transparent lens 1001 may further include at least one reflective member that reflects the augmented reality content image provided from the at least one image display module 1010 towards the transparent lens 1001 or the user's eyes, and optical members that adjust a focus and a size. One or more reflective member may be built in the transparent lens 1001 to be integrated with the transparent lens 1001, and may be formed as a plurality of refractive lenses or a plurality of prisms with a selected curvature.

The at least one image display module 1010 may include a micro LED display device (micro-LED), a nano LED display device (nano-LED), an organic light-emitting display device (OLED), an inorganic light-emitting display device (inorganic EL), a quantum dot light-emitting display device (QED), a cathode ray display (CRT), a liquid crystal display (LCD), or the like. The image display module 1010 may substantially include the display device 10 described with reference to FIG. 1 or the like.

The surrounding environment detector 1040 is assembled or integrally formed with the support frame 1002, and detects the distance (or depth) to an object on the front side of the support frame 1002, the illuminance, the moving direction of the support frame 1002, the moving distance, the tilt, or the like. For example, the surrounding environment detector 1040 includes a depth sensor 1041 such as an infrared sensor or a LiDAR sensor, and an image sensor 1050 such as a camera. Further, the surrounding environment detector 1040 may further include at least one motion sensor among an illumination sensor, a human body detection sensor, a gyro sensor, a tilt sensor, and an acceleration sensor. Further, the surrounding environment detector 1040 may further include first and second biometric sensors 1031 and 1032 for detecting movement information of the user's eyes or pupils.

The surrounding environment detector 1040 may transmit sensing signals generated in real time by the depth sensor 1041 and at least one motion sensor to the control module 1020 for processing in real time. Further, the image sensor 1050 may transmit image data in units of at least one frame generated in real time to the control module 1020 for processing in real time. Moreover, the first and second biometric sensors 1031 and 1032 of the surrounding environment detector 1040 may transmit the detected pupil detection signals generated in real time to the control module 1020 for processing in real time.

The control module 1020 may be assembled to at least one side of the support frame 1002 together with the at least one image display module 1010 or may be formed integrally with the support frame 1002. The control module 1020 supplies augmented reality content data to the at least one image display module 1010 where the at least one image display module 1010 displays an augmented reality content, e.g., an augmented reality content image. For example, the control module 1020 may receive sensing signals, image data, and pupil detection signals from the surrounding environment detector 1040 in real time.

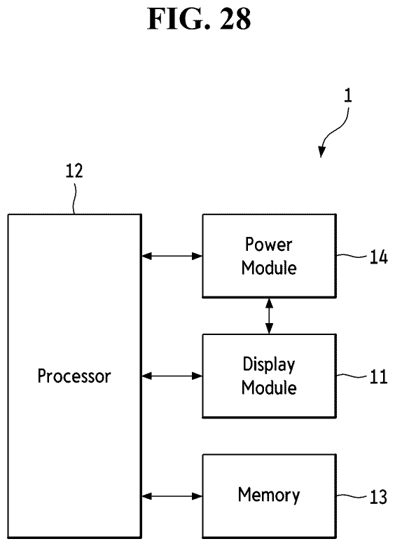

Moreover, the display device 10 according to the above-described embodiments may be applied to various electronic devices 1, such as shown in FIG. 28, described infra, in addition to the head-mounted display 1000 and the augmented reality content providing device 1000_1 described above. An electronic device 1, such as shown in FIG. 28, described infra, according to an embodiment may include the above-described display device 10, and may further include, in addition to the display device 10, a module or device having other additional functions.

FIG. 28 shows an electronic device according to an embodiment, indicated generally by the reference indicator 1.

Referring to FIG. 28, the electronic device 1 according to an embodiment may include a display module 11, a processor 12, a memory 13, and a power module 14.

The processor 12 may include at least one of a central processing unit (CPU), an application processor (AP), a graphic processing unit (GPU), a communications processor (CP), an image signal processor (ISP), or a controller.

The memory 13 may store data information for the operation of the processor 12 or the display module 11. When the processor 12 executes an application stored in the memory 13, an image data signal and/or an input control signal is transmitted to the display module 11, and the display module 11 may process the received signal and output image information through a display screen.

The power module 14 may include a power supply module, such as a power adapter or a battery device, and a power conversion module that converts power supplied by the power supply module to generate power for the operation of the electronic device 1.

At least one of the components of the electronic device 1 described above may be included in the display device 10 according to the embodiments described above. Further, some of the individual modules functionally included in one module may be included in the display device 10 and some others may be provided separately from the display device 10. For example, the display device 10 may include the display module 11, and the processor 12, the memory 13, and the power module 14 may be configured in the form of other devices in the electronic device 1 other than the display device 10.

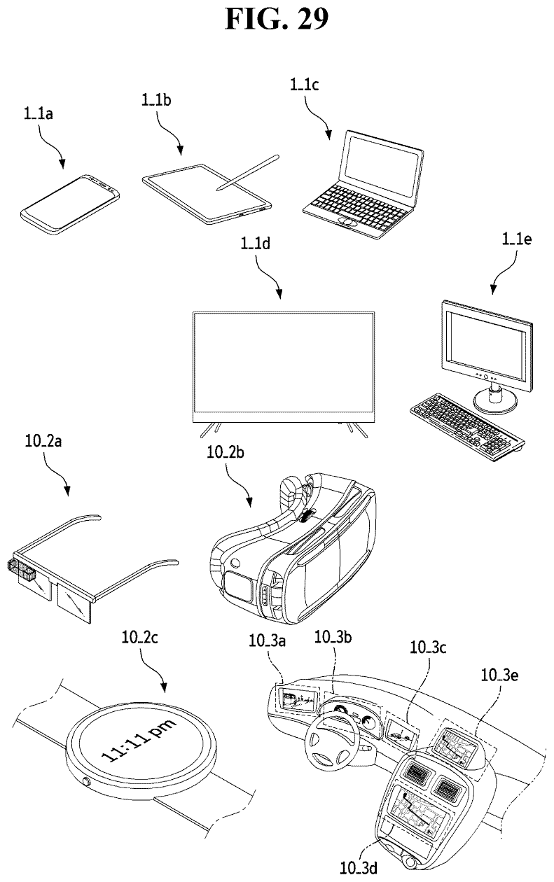

FIG. 29 shows electronic devices according to various embodiments, indicated generally by the reference indicators 1.1, 1.2 and 1.3.

Referring to FIG. 29, various electronic devices to which the display device 10 according to embodiments is applied may include not only an image display electronic device 1_1 such as a smartphone 1_1a, a tablet computer 1_1b, a laptop computer 1_1c, a television 1_1d, and a desktop computer monitor 1_1e, but also a wearable electronic device 1_2 including a display module, such as a smart glasses 1_2a, a head-mounted display 1_2b, a smart watch 1_2c, or the like, a vehicle electronic device 1_3 including a display module, such as a driver's left display 1_3a, an instrument cluster display 1_3b, a driver's right display 1_3c, a center fascia display 1_3d, a dashboard of an automobile having a center information display (CID) 1.3e placed thereon, a vehicular or room mirror display, or the like.

In concluding the detailed description, those of ordinary skill in the pertinent art will appreciate that many variations and modifications can be made to the illustrative embodiments without substantially departing from the principles, scope or spirit of the present disclosure. Therefore, the disclosed embodiments of the inventive concept are used in a generic and descriptive sense and not necessarily for purposes of limitation.

What is claimed is:

1. A display device comprising:
a display panel;
a first polarizing film located on the display panel;
a first phase retardation film located on the first polarizing film;
a reflection control film located on the first phase retardation film;
a first lens located on the reflection control film;
a second lens located on the first lens;
a second phase retardation film located on the second lens;
a second polarizing film located on the second phase retardation film; and
a third lens located on the second polarizing film,
wherein a first function of a transmittance and a reflectivity of the reflection control film in respect to light of a first wavelength range is different from the first function of a transmittance and a reflectivity of the reflection control film in respect to light of a second wavelength range.

2. The display device of claim 1,
wherein the first function is a product of transmittance and reflectivity in respect to light of a same wavelength range.

3. The display device of claim 1,
wherein the display panel emits light of the first wavelength range, the second wavelength range, and a third wavelength range,
wherein the first function of the transmittance and the reflectivity of the reflection control film in respect to the light of the first wavelength range is smaller than the first function of the transmittance and the reflectivity of the reflection control film in respect to the light of the second wavelength range and the third wavelength range.

4. The display device of claim 3,
wherein the first wavelength range is a red wavelength band from about 620 nm to about 640 nm, the second wavelength range is a green wavelength band about 515 nm to about 535 nm, and the third wavelength range is a blue wavelength band from about 450 nm to about 470 nm,
wherein a full width at half maximum of main peak wavelengths included in the first wavelength range and the second wavelength range is about 30 nm to about 40 nm, and a full width at half maximum of main peak wavelength included in the third wavelength range is about 20 nm to about 30 nm.

5. The display device of claim 3,
wherein the first function of the transmittance and the reflectivity of the reflection control film in respect to light of the first to third wavelength ranges is greater than the first function of the transmittance and the reflectivity of the reflection control film in respect to the light of a range other than the first to third wavelength ranges.

6. The display device of claim 1,
wherein a second function of the transmittance and the reflectivity of the reflection control film in respect to light of the first wavelength range is substantially the same as the second function of the transmittance and the reflectivity of the reflection control film in respect to light of the second wavelength range.

7. The display device of claim 6,
wherein the second function is a sum of transmittance and reflectivity in respect to light of a same wavelength range,
wherein the sum of the transmittance and the reflectivity of the reflection control film in respect to the same wavelength within the second wavelength range is substantially 100%.

8. The display device of claim 1,
wherein the reflection control film includes multiple films in which low-refractive-index films and high-refractive-index films are alternatively stacked,
wherein the low-refractive-index film contains at least one among silicon oxide and silicon oxynitride,
wherein the high-refractive-index film contains at least one among silicon nitride and titanium oxide.

9. The display device of claim 1,
wherein the first lens, the second lens, and the third lens are spaced apart from each other,
the display device further comprising at least one reflective coating film located between the first lens and the second lens and between the second lens and the third lens, respectively.

10. The display device of claim 1,
wherein the first lens, the second lens, and the third lens are combined to form a triplet lens,
the display device further comprising:
a first adhesive layer located between the first lens and the second lens; and
a second adhesive layer located between the second lens and the third lens.

11. The display device of claim 1,
wherein the first lens and the second lens are combined to form a doublet lens,
wherein the doublet lens and the third lens are spaced apart from each other,
the display device further comprising:
an adhesive layer located between the first lens and the second lens; and
at least one reflective coating film located between the doublet lens and the third lens.

12. The display device of claim 1,
wherein the second lens and the third lens are combined to form a doublet lens,
wherein the doublet lens and the first lens are spaced apart from each other,
the display device further comprising:
an adhesive layer located between the second lens and the third lens; and
at least one reflective coating film located between the doublet lens and the first lens.

13. The display device of claim 1,
wherein the transmittance of the reflection control film in respect to light of the first wavelength range is different from the transmittance of the reflection control film in respect to light of the second wavelength range.

14. The display device of claim 13,
wherein the sum of the transmittance and a reflectivity of the reflection control film in respect to the same wavelength range is substantially 100%.

15. A display device comprising:
a display panel; and
a reflection control film located on the display panel,
wherein a first function of a transmittance and a reflectivity of the reflection control film in respect to light of a first wavelength range is different from the first function of a transmittance and a reflectivity of the reflection control film in respect to light of a second wavelength range,
wherein a second function of the transmittance and the reflectivity of the reflection control film in respect to light of the first wavelength range is substantially the same as the second function of the transmittance and the reflectivity of the reflection control film in respect to light of the second wavelength range.

16. The display device of claim 15,
wherein the first function is a product of transmittance and reflectivity in respect to light of a same wavelength range,
wherein the second function is a sum of transmittance and reflectivity in respect to light of the same wavelength range.

17. The display device of claim 16, further comprising:
a first polarizing film disposed on the display panel; and
a first phase retardation film disposed on the first polarizing film,
wherein the reflection control film is disposed on the first phase retardation film.

18. The display device of claim 17, further comprising:
a first lens disposed on the reflection control film;
a second lens disposed on the first lens;
a second phase retardation film disposed on the second lens;
a second polarizing film disposed on the second phase retardation film; and
a third lens disposed on the second polarizing film.

19. An electronic device comprising:
a display device displaying an image;
a processor providing an image driving signal to the display device; and
a power module supplying power to the display device and the processor,
wherein the display device comprises:
a display panel;
a first polarizing film located on the display panel;
a first phase retardation film located on the first polarizing film;
a reflection control film located on the first phase retardation film;
a first lens located on the reflection control film;
a second lens located on the first lens;
a second phase retardation film located on the second lens;
a second polarizing film located on the second phase retardation film; and
a third lens located on the second polarizing film,
wherein the product of a transmittance and a reflectivity of the reflection control film in respect to light of a first wavelength range is different from the product of the transmittance and the reflectivity of the reflection control film in respect to light of a second wavelength range.

20. The electronic device of claim 19,
wherein the sum of the transmittance and the reflectivity of the reflection control film in respect to light of the first wavelength range is substantially the same as the sum of the transmittance and the reflectivity of the reflection control film in respect to light of the second wavelength range.
